(19) United States
(12) Patent Application Publication
(10) Pub. No.: US 2026/0196451 A1
(43) Pub. Date: Jul. 9, 2026

(54) SUBSTRATE PROCESSING APPARATUS AND SUBSTRATE PROCESSING SYSTEM

(71) Applicant: Tokyo Electron Limited, Tokyo (JP)

(72) Inventor: Nobuyuki NAGAYAMA, Miyagi (JP)

(73) Assignee: Tokyo Electron Limited, Tokyo (JP)

(21) Appl. No.: 19/551,615

(22) Filed: Feb. 27, 2026

Related U.S. Application Data
(63) Continuation of application No. PCT/JP2024/029275, filed on Aug. 19, 2024.

(30) Foreign Application Priority Data
Sep. 1, 2023 (JP) 2023-142542

(51) Int. Cl. H01J 37/32; H10P 72/76

(52) U.S. Cl. CPC H01J 37/32724; H01J 37/3244; H10P 72/7611; H10P 72/7612; H01J 2237/334

(57) ABSTRACT

A substrate processing apparatus to process a substrate, the substrate processing apparatus including: a processing chamber; and a support member disposed in the processing chamber and having a tray supporting surface for supporting a tray on an upper surface of the support member, in which the tray includes a recess accommodating the substrate on an upper surface of the tray via a first heat transfer material, and the tray supporting surface includes a second heat transfer material is interposed between the tray supporting surface and a lower surface side of the tray.

### CROSS-REFERENCE TO RELATED APPLICATIONS

This application is a Continuation of PCT International Application No. PCT/JP2024/029275, filed on Aug. 19, 2024, which claims priority under 35 U.S.C. § 119(a) to Japanese Patent Application No. 2023-142542, filed in Japan on Sep. 1, 2023, all of which are hereby expressly incorporated by reference into the present application.

### BACKGROUND

### Field

The present disclosure relates to a substrate processing apparatus and a substrate processing system.

### Description of Related Art

JP 2021-34390 A discloses that in a substrate processing system processing a substrate, a wafer as a substrate processing target and an edge ring disposed to surround the wafer are electrostatically adsorbed to a tray having a disk-like shape, and are transported to a process module in this state. In addition, in the substrate processing system described in JP 2021-34390 A, it is disclosed that the wafer and the edge ring are placed on a susceptor in a process module via the tray, and plasma processing such as etching is performed in this state.

### SUMMARY

One aspect of the present disclosure relates to a substrate processing apparatus configured to process a substrate, the substrate processing apparatus including: a processing chamber; and a support member disposed in the processing chamber and having a tray supporting surface for supporting a tray on an upper surface of the support member, in which the tray is formed with a recess accommodating the substrate on an upper surface of the tray via a first heat transfer material, and the tray supporting surface is configured in such a manner that a second heat transfer material is interposed between the tray supporting surface and a lower surface side of the tray.

### BRIEF DESCRIPTION OF DRAWINGS

FIG. 1 is a plan view schematically illustrating an example of a configuration of a wafer processing system.

FIG. 2 is a cross-sectional view schematically illustrating an example of a configuration of a wafer processing module.

FIG. 3 is a diagram illustrating a flow of wafer processing in the wafer processing system.

FIG. 4 is a cross-sectional view schematically illustrating an example of a configuration of a tray according to the present embodiment.

FIG. 5 is a schematic cross-sectional view illustrating a spacer provided in the tray.

FIG. 6 is a schematic cross-sectional view illustrating another mounting method of the wafer on the tray.

FIG. 7 is a cross-sectional view schematically illustrating another configuration example of the tray.

FIG. 8 is a cross-sectional view schematically illustrating another configuration example of the tray.

FIG. 9 is a cross-sectional view schematically illustrating another configuration example of the tray.

FIG. 10 is a cross-sectional view schematically illustrating another configuration example of the tray.

FIG. 11 is a cross-sectional view schematically illustrating another configuration example of the tray.

FIG. 12 is a cross-sectional view schematically illustrating an example of a supplying method of a liquid heat transfer material to the tray.

FIG. 13 is a timing chart illustrating a flow of the supplying method of the liquid heat transfer material to the tray.

FIG. 14 is a cross-sectional view schematically illustrating an example of the supplying method of the liquid heat transfer material to the tray.

FIG. 15 is a diagram illustrating a flow of the wafer processing when the liquid heat transfer material is used.

FIG. 16 is a diagram illustrating a flow of the wafer processing when a sheet heat transfer material is used.

FIG. 17 is a cross-sectional view schematically illustrating another configuration example of the tray.

FIG. 18 is an explanatory view illustrating an example of a mounting/separating method of the wafer with respect to the tray.

FIG. 19 is an explanatory view illustrating an example of a separating method of the wafer from the tray.

FIG. 20 is an explanatory view illustrating an example of the separating method of the wafer from the tray.

FIG. 21 is an explanatory view illustrating an example of the separating method of the wafer from the tray.

FIG. 22 is an explanatory view illustrating an example of the separating method of the wafer from the tray.

FIG. 23 is a cross-sectional view schematically illustrating another configuration example of the tray.

FIG. 24 is a cross-sectional view schematically illustrating another configuration example of the tray.

FIG. 25 is a cross-sectional view schematically illustrating another configuration example of the tray.

FIG. 26 is an explanatory view illustrating an example of a transporting method of the tray.

FIG. 27 is a cross-sectional view schematically illustrating an example of a fixing method of the tray to a support member.

FIG. 28 is a cross-sectional view schematically illustrating an example of the fixing method of the tray to the support member.

FIG. 29 is an explanatory view illustrating an example of sheath control using an electrostatic chuck.

FIG. 30 is an explanatory view illustrating an example of sheath control using the electrostatic chuck.

FIG. 31 is a cross-sectional view schematically illustrating an example of the fixing method of the tray to the support member.

FIG. 32 is a perspective view illustrating a configuration example of a lock mechanism fixing the tray to the support member.

FIG. 33 is a cross-sectional view schematically illustrating an example of the fixing method of the tray to the support member.

FIG. 34 is a cross-sectional view schematically illustrating an example of the fixing method of the tray to the support member.

FIG. 35 is a cross-sectional view schematically illustrating an example of a separating method of the tray from the support member.

FIG. 36 is a cross-sectional view schematically illustrating another configuration example of the support member.

FIG. 37 is a plan view schematically illustrating another configuration example of the support member.

FIG. 38 is a cross-sectional view schematically illustrating a configuration example of a cleaning tray.

FIG. 39 is a plan view schematically illustrating a configuration example of the cleaning tray.

FIG. 40 is a plan view schematically illustrating a configuration example of the cleaning tray.

### DETAILED DESCRIPTION

In a manufacturing process of a semiconductor device, various types of plasma processing such as etching processing, film forming processing, and diffusion processing are performed on a semiconductor substrate (hereinafter, may be referred to as a “wafer”). In such plasma processing, in order to obtain an in-plane uniform processing result on the wafer, it is important to keep a temperature of the wafer being processed uniformly in the plane.

In a substrate processing system, when the wafer as a substrate processing target and an edge ring are adsorbed and held on a disk-shaped tray, and are transported to a process module and subjected to plasma processing in this state, for example, it is required to suppress the occurrence of temperature singular points at a contact point with a lift pin that delivers the tray to a susceptor, and an outer peripheral portion of the wafer that does not directly come into contact with the susceptor.

The technique of the present disclosure is made in view of the above circumstances, and appropriately improves the in-plane temperature uniformity of the substrate in the substrate processing. Hereinafter, a wafer processing system including a wafer processing module according to the present embodiment will be described with reference to the drawings. In the present specification and the drawings, elements having substantially the same functional configuration are denoted by the same reference numerals, and redundant description thereof will be omitted.

### <Wafer Processing System>

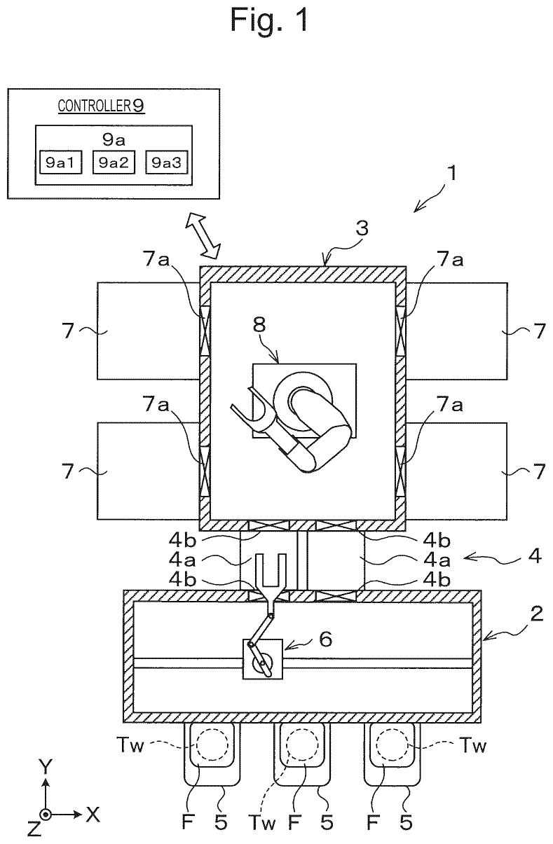

FIG. 1 is a plan view schematically illustrating an outline of a configuration of a wafer processing system 1.

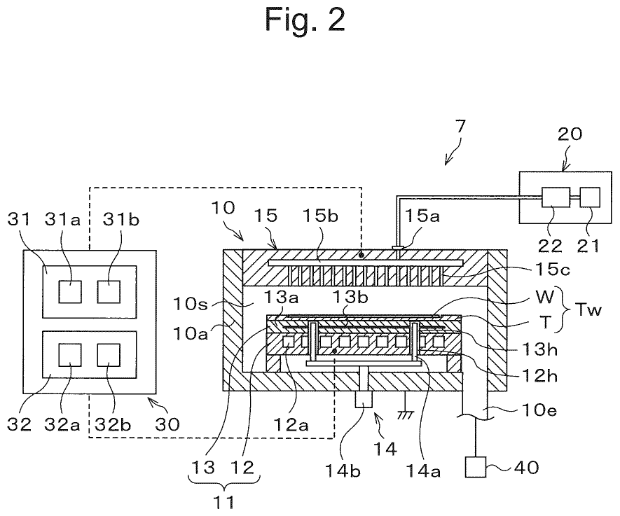

In the wafer processing system 1, various types of processing are performed on a wafer W as a substrate. The wafer W is an example of the substrate. The wafer W is, for example, a semiconductor wafer such as a semiconductor substrate, and in an embodiment, a device layer (not illustrated) including multiple devices is formed on a surface thereof. In the wafer processing system 1 according to the present embodiment, the wafer W as a processing target is transported and processed in a state of being placed on a tray T described later (see FIG. 2). The wafer W is mounted on the tray T in a state where a surface on which the device layer is formed faces upward. Hereinafter, for simplification of description, the tray T in a state of holding the wafer W transported and processed by the wafer processing system 1 may be referred to as a “tray Tw”. A detailed configuration of the tray T will be described later.

In the following embodiment, a case where the device layer is formed on the surface of the wafer W as described above will be described as an example, but the wafer W does not necessarily have to be a device wafer on which the device layer is formed.

As illustrated in FIG. 1, the wafer processing system 1 has a configuration in which an atmospheric transport module 2 and a vacuum transport module 3 are integrally connected via a load lock module 4. The atmospheric transport module 2 transports the tray Tw in an atmospheric environment. The vacuum transport module 3 transports the tray Tw in a vacuum (depressurized) atmosphere.

The load lock module 4 has one or more, for example, two load lock chambers 4a in the present embodiment. The load lock chamber 4a is provided in such a manner that an interior space of the atmospheric transport module 2 and an interior space of the vacuum transport module 3 communicate with each other via a transport port. The transport port is configured to be openable and closable by a gate valve 4b.

The load lock module 4 is configured to temporarily hold the tray Tw. In addition, the load lock module 4 is configured to switch an inside to the atmospheric atmosphere and the depressurized atmosphere (vacuum state). That is, the load lock module 4 is configured in such a manner that the tray Tw can be appropriately delivered between the atmospheric transport module 2 in the atmospheric environment and the vacuum transport module 3 in the depressurized environment.

The atmospheric transport module 2 consists of a housing having a rectangular interior, and an inside of the housing is maintained in the atmospheric environment. A plurality of, for example, three load ports 5 are connected side by side on one side surface constituting a long side of the atmospheric transport module 2 on a Y-axis negative direction side. The two load lock chambers 4a described above are connected side by side on the other side surface constituting a long side of the atmospheric transport module 2 on a Y-axis positive direction side. The atmospheric transport module 2 may be further connected to an orienting module (not illustrated) that adjusts an orientation of the tray Tw in a horizontal direction, a storage module (not illustrated) that stores multiple trays Tw, or the like.

FOUPs F capable of storing the multiple trays Tw are placed on the load port 5. A ceiling transport mechanism (OHT: not illustrated) movable along a rail disposed on a ceiling surface of a clean room in which the wafer processing system 1 is disposed is provided above the wafer processing system 1, and the FOUP F accesses the wafer processing system 1 via the ceiling transport mechanism and is delivered to the load port 5.

In addition, a first transport mechanism 6 transporting the tray Tw is provided inside the atmospheric transport module 2. The first transport mechanism 6 is configured to transport the tray Tw between the FOUP F of the load port 5 and the load lock chamber 4a of the load lock module 4. A configuration of the first transport mechanism 6 is not particularly limited.

The vacuum transport module 3 consists of a housing having a rectangular shape in a plane, and the inside of the housing can be maintained in the vacuum (depressurized) atmosphere. A plurality of, for example, four wafer processing modules 7 are connected to a side surface of the vacuum transport module 3. An interior space of the wafer processing module 7 communicates with the interior space of the vacuum transport module 3 via a transport port. The transport port is configured to be openable and closable by a gate valve 7a. The number and disposition of the wafer processing modules 7 are not limited to the present embodiment and can be set as desired.

In addition, a second transport mechanism 8 transporting the tray Tw is provided inside the vacuum transport module 3. The second transport mechanism 8 is configured to be able to transport the tray Tw between the load lock chamber 4a of the load lock module 4 and one or more wafer processing modules 7. A configuration of the second transport mechanism 8 is not particularly limited.

In the wafer processing module 7 as a substrate processing apparatus, in an example, plasma processing such as etching processing is performed on the wafer W placed on the tray T. FIG. 2 is a diagram illustrating, as an example, a case where the wafer processing module 7 is a capacitively coupled plasma processing apparatus.

The wafer processing module 7, which is the capacitively coupled plasma processing apparatus, includes a plasma processing chamber 10, a gas supply 20, a power supply 30, and an exhaust system 40. In addition, the wafer processing module 7 includes a support member 11 and a gas introducer. The gas introducer is configured to introduce at least one processing gas into the plasma processing chamber 10. The gas introducer includes a shower head 15. The support member 11 is disposed in the plasma processing chamber 10. The shower head 15 is disposed above the support member 11. In an embodiment, the shower head 15 constitutes at least a part of a ceiling of the plasma processing chamber 10. The plasma processing chamber 10 has a plasma processing space 10s defined by the shower head 15, a side wall 10a of the plasma processing chamber 10, and the support member 11. The plasma processing chamber 10 is grounded. The shower head 15 and the support member 11 are electrically insulated from the housing of the plasma processing chamber 10.

The support member 11 includes a base 12, an electrostatic chuck 13, and a lifter 14. The base 12 includes a conductive member. The conductive member of the base 12 may function as a lower electrode. The electrostatic chuck 13 is disposed on the base 12. The electrostatic chuck 13 includes a ceramic member 13a and an electrostatic electrode 13b disposed in the ceramic member 13a. The ceramic member 13a is made of a dielectric material and has a tray supporting surface for supporting the tray Tw. In an embodiment, the tray supporting surface of the ceramic member 13a has a diameter larger than that of the wafer W placed on the tray T, and smaller than or substantially the same as that of the tray T.

Further, at least one RF/DC electrode coupled to an RF power supply 31 and/or a DC power supply 32, which will be described later, may be disposed in the ceramic member 13a. In this case, at least one RF/DC electrode functions as the lower electrode. When a bias RF signal and/or a DC signal, which will be described later, are supplied to at least one RF/DC electrode, the RF/DC electrode is also referred to as a bias electrode. The conductive member of the base 12 and at least one RF/DC electrode may function as the lower electrodes. Further, the electrostatic electrode 13b may function as the lower electrode. Therefore, the support member 11 includes at least one lower electrode.

The lifter 14 has multiple (three in the present embodiment) lift pins 14a and an actuator 14b which is a drive mechanism for moving the lift pins 14a in a vertical direction. Multiple (three in the present embodiment) through-holes 12h and 13h penetrating each of the base 12 and the electrostatic chuck 13 in a thickness direction are formed in the base 12 and the electrostatic chuck 13, and each of the lift pins 14a of the lifter 14 is inserted into the through-holes 12h and 13h. An example of the actuator 14b includes an electric actuator, an air cylinder, a motor, and the like.

Then, the lifter 14 moves the lift pin 14a in an axial direction (vertical direction) by the actuator 14b to lift and lower the tray Tw on the electrostatic chuck 13. As a result, the tray Tw is moved between a delivery height at which the tray Tw is delivered to the second transport mechanism 8 and a processing height at which the wafer processing is performed on the electrostatic chuck 13.

In addition, the support member 11 may include a temperature-controlled module configured to adjust at least one of the electrostatic chuck 13, the tray T, and the wafer W to a target temperature. The temperature-controlled module may include a heater, a heat transfer medium, a flow path 12a, or a combination thereof. A heat transfer fluid such as brine or a gas flows in the flow path 12a. In an embodiment, the flow path 12a is formed in the base 12, and one or multiple heaters are disposed in the ceramic member 13a of the electrostatic chuck 13. In addition, the support member 11 may include a gas supply configured to supply a gas (for example, a nitrogen (N₂) gas) to a gap between a back surface of the tray T and the tray supporting surface of the electrostatic chuck 13. This gas supply may be shared with the gas supply 20 described later.

The shower head 15 is configured to introduce at least one processing gas into the plasma processing space 10s from the gas supply 20. The shower head 15 has at least one gas supply port 15a, at least one gas diffusion chamber 15b, and multiple gas introduction ports 15c. The processing gas supplied to the gas supply port 15a passes via the gas diffusion chamber 15b and is introduced into the plasma processing space 10s from the multiple gas introduction ports 15c. In addition, the shower head 15 includes at least one upper electrode. In addition to the shower head 15, the gas introducer may include one or multiple side gas injectors (SGI) attached to one or multiple opening portions formed on the side wall 10a.

The gas supply 20 may include at least one gas source 21 and at least one flow rate controller 22. In an embodiment, the gas supply 20 is configured to supply at least one processing gas to the shower head 15 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, the plasma is formed from at least one processing gas supplied to the plasma processing space 10s. Therefore, the RF power supply 31 may function as at least a part of a plasma generator. In addition, by supplying the bias RF signal to at least one lower electrode, a bias potential is generated in the wafer W, and an ion component in the formed plasma can be drawn into the wafer W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate source RF signals having different frequencies. The generated one or multiple source RF signals are supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has the frequency in the range of 100 kHz to 60 MHz. In an embodiment, the second RF generator 31b may be configured to generate bias RF signals having different frequencies. The generated one or multiple bias RF signals are supplied to at least one lower electrode. In addition, in various embodiments, at least one of the source RF signal and the bias RF signal may be pulsed.

In addition, the power supply 30 may include the DC power supply 32 coupled to the plasma processing chamber 10. The DC power supply 32 includes the first DC generator 32a and the second DC generator 32b. In an embodiment, the first DC generator 32a is connected to at least one lower electrode, and is configured to generate a first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator constitute a voltage pulse generator. When the second DC generator 32b and the waveform generator constitute the voltage pulse generator, the voltage pulse generator is connected to at least one upper electrode. The voltage pulse may have a positive polarity or a negative polarity. In addition, the sequence of voltage pulses may include one or multiple voltage pulses of the positive polarity and one or multiple voltage pulses of the negative polarity in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

The wafer processing module 7 is configured as described above in an example, but the configuration of the wafer processing module 7 is not limited thereto.

For example, in the example illustrated in FIG. 2, a case where the plasma generator of the wafer processing module 7 generates a capacitively coupled plasma (CCP) is described as an example. However, the plasma formed by the plasma generator may be an inductively coupled plasma (ICP), an electron-cyclotron-resonance plasma (ECR plasma), a helicon wave plasma (HWP), a surface wave plasma (SWP), or the like. In addition, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHz. Therefore, the AC signal includes a radio frequency (RF) signal and a microwave signal. In an embodiment, the RF signal has a frequency in the range of 100 KHz to 150 MHz.

Return to the description of FIG. 1.

As illustrated in FIG. 1, the wafer processing system 1 is provided with a controller 9. The controller 9 processes a computer-executable command for causing the wafer processing system 1 to execute various steps described in the present disclosure. The controller 9 may be configured to control each element of the wafer processing system 1 to execute various steps described here. In an embodiment, a part or all of the controller 9 may be included in the wafer processing system 1. The controller 9 may include a processor 9a1, a storage 9a2, and a communication interface 9a3. The controller 9 is realized by, for example, a computer 9a. The processor 9a1 may be configured to read out a program from the storage 9a2, and perform various control operations by executing the read out program. This program may be stored in the storage 9a2 in advance, or may be acquired via a medium when necessary. The acquired program is stored in the storage 9a2, and is read out from the storage 9a2 and executed by the processor 9a1. The medium may be various storage media readable by the computer 9a or may be a communication line connected to the communication interface 9a3. The processor 9a1 may be a central processing unit (CPU). The storage 9a2 may include a random access memory (RAM), a read only memory (ROM), a hard disk drive (HDD), a solid state drive (SSD), or a combination thereof. The communication interface 9a3 may communicate with the wafer processing system 1 via a communication line such as a local area network (LAN). In addition, the storage medium described above may be a temporary storage medium or a non-temporary storage medium. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

### <Processing Flow in Wafer Processing System>

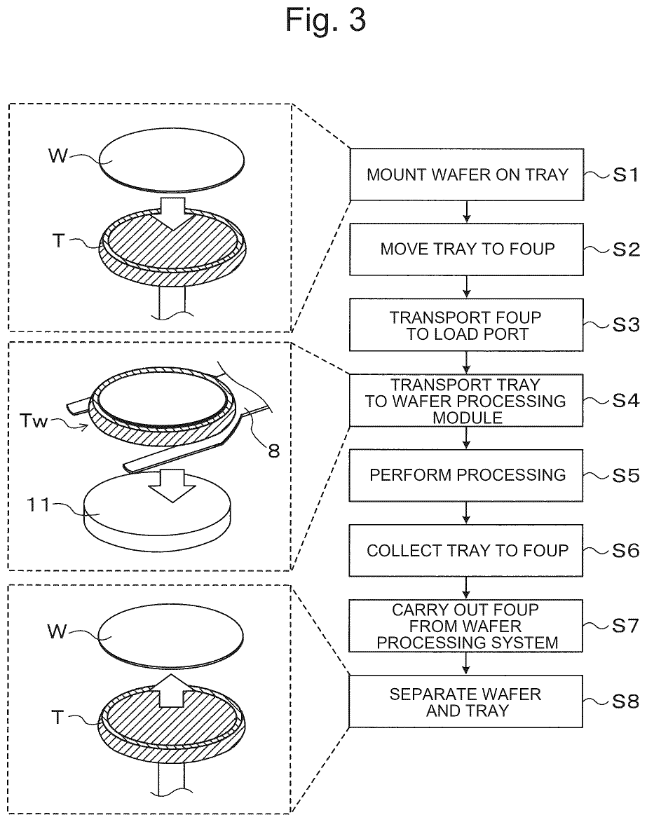

Next, the wafer processing performed using the wafer processing system 1 configured as described above will be described along a flow of the transportation of the tray Tw. FIG. 3 is a diagram illustrating main steps of the wafer processing. As described above, in the following description, a case where the wafer W is a device wafer in which the device layer is formed on a front surface side will be described as an example, but the wafer W may not have the device layer formed thereon.

First, before the FOUP F is transported to the wafer processing system 1, a mounting apparatus (not illustrated) provided outside the wafer processing system 1 mounts the wafer W as a processing target on the tray T, and prepares the tray Tw on which the wafer W is mounted (step S1 in FIG. 3). In this case, the wafer W is mounted on the tray T in a state where the front surface side on which the device layer is formed faces upward. The tray Tw on which the wafer W is mounted is accommodated in the FOUP F (step S2 in FIG. 3). In the FOUP F, the tray Tw is accommodated in a state where a wafer supporting surface side on which the wafer W is mounted faces upward.

Next, the FOUPs F accommodating trays Tw are transported by the ceiling transport mechanism (OHT) (not illustrated) and are mounted on the load port 5 of the wafer processing system 1 (step S3 in FIG. 3). Next, the tray Tw is taken out from the FOUP F by the first transport mechanism 6 and is transported to one wafer processing module 7 via the load lock chamber 4a of the load lock module 4 and the second transport mechanism 8. In the wafer processing module 7, a back surface side (surface on a side opposite to the wafer supporting surface on which the wafer W is placed) of the tray Tw on which the wafer W is mounted is adsorbed and held by the electrostatic chuck 13 of the support member 11 (step S4 in FIG. 3). As will be described later, for example, when the wafer W and the support member 11 come into sufficient contact with each other by a weight of the tray Tw, and the wafer W can be sufficiently cooled, the electrostatic adsorption by the electrostatic chuck 13 is not always necessary.

In the wafer processing module 7, any processing according to the purpose of the wafer processing, for example, plasma processing such as etching is performed (step S5 in FIG. 3).

Specifically, for example, after the wafer W is carried in, the inside of the plasma processing chamber 10 is depressurized to a desired degree of vacuum, and then a desired processing gas is supplied to the plasma processing space 10s. Thereafter, at least one RF signal (RF power) is supplied to at least one lower electrode and/or at least one upper electrode by the RF power supply 31, and the processing gas is excited to form the plasma. Then, the wafer W is subjected to the plasma processing by the action of the plasma formed in this manner. In this case, the plasma processing on the wafer W is performed in a state where the wafer W is placed on the tray T.

When the desired wafer processing is performed on the wafer W, the tray Tw is carried out from the wafer processing module 7 by the second transport mechanism 8. The tray Tw carried out from the wafer processing module 7 is collected to the FOUP F via the load lock chamber 4a of the load lock module 4 and the first transport mechanism 6 (step S6 in FIG. 3).

Next, the FOUP F accommodating the processed wafer W is carried out from the wafer processing system 1 by the ceiling transport mechanism (OHT) (not illustrated) (step S7 in FIG. 3).

Then, the tray T and the wafer W are separated by a separation apparatus (not illustrated) provided outside the wafer processing system 1 (step S8 in FIG. 3). In this way, a series of wafer processing using the wafer processing system 1 is ended.

According to the present embodiment, as described above, in a state where the wafer W as a processing target is mounted on the tray T, the transport in the wafer processing system 1 and the wafer processing in the wafer processing module 7 are sequentially performed.

In the above description, as illustrated in FIG. 3, a case where the wafer W is mounted on the tray T in advance outside the wafer processing system 1, in other words, a case where the tray Tw is carried into the wafer processing system 1 is described as an example. However, the mounting of the wafer W on the tray T does not necessarily have to be performed outside the wafer processing system 1, and may be performed inside the wafer processing system 1. In this case, the FOUPs F accommodating trays T and FOUPs F accommodating wafers W are respectively carried into the wafer processing system 1, and for example, in a mounting apparatus (not illustrated)/a separation apparatus (not illustrated) disposed to be connected to the atmospheric transport module 2, the wafers W are mounted on/separated from the trays T. In addition, in this case, the mounting apparatus and the separation apparatus may be independently disposed to mount/separate the wafer W with respect to the tray T in different apparatuses, or the mounting apparatus and the separation apparatus may be integrally configured to mount/separate the wafer W with respect to the tray T in the same apparatus.

### <Detailed Structure of Tray>

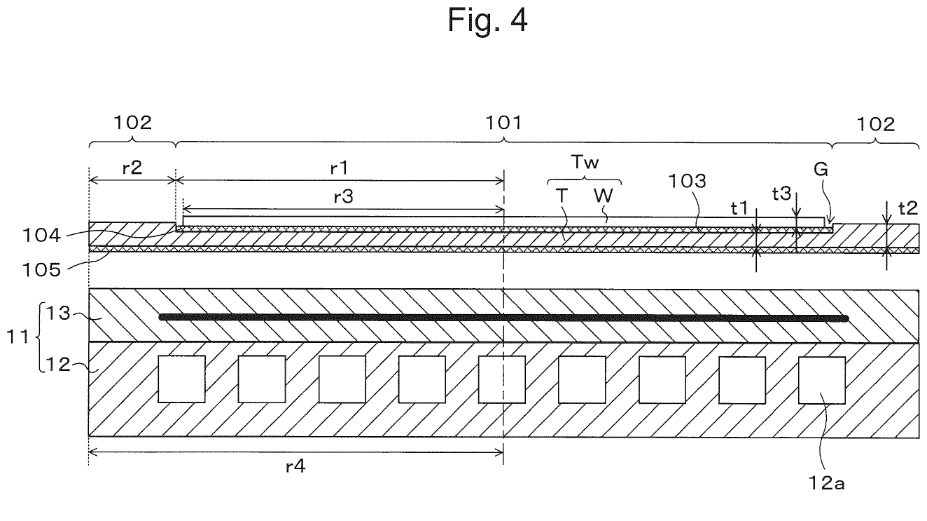

Next, a detailed structure of the tray T on which the wafer W is mounted will be described. FIG. 4 is a cross-sectional view schematically illustrating an example of a configuration of the tray T, and illustrates a state where the tray T is disposed above the support member 11 of the wafer processing module 7. In FIG. 4, the through-holes 12h and 13h are omitted for simplicity of illustration.

As illustrated in FIG. 4, the tray T has a substantially disk shape and has a cross-sectional recess shape in which a thickness of a center portion is smaller than a thickness of an outer peripheral portion in cross-sectional view. Hereinafter, the center portion of the tray T having a small thickness in cross-sectional view is referred to as a “disk portion 101”, and an outer peripheral portion of the tray T having a large thickness in cross-sectional view is referred to as an “annular portion 102”, respectively, for convenience. In addition, a cross-sectional recess shape formed by the disk portion 101 and the annular portion 102 may be referred to as a “recess 103”. In addition, the tray T includes a first heat transfer material 104 disposed between the wafer W and an upper surface of the disk portion 101 when the wafer W is accommodated, and a second heat transfer material 105 disposed between the tray placement surface and a lower surface of the disk portion 101 when the tray T is placed on the tray placement surface of the electrostatic chuck 13.

The disk portion 101 is composed of, for example, at least one material selected from Si, SiC, SiN, C, SiO2, Al2O3, Y2O3, YOF, W, Ti, TiN, ZeO2, and a green sheet. Therefore, the disk portion 101 may be made of a conductive material or an insulating material. In addition, a relative dielectric constant of the disk portion 101 may be 8.0 or less. In addition, a volume resistivity of the disk portion 101 may be, for example, 1×10e12 [Ω·cm] or less when the electrostatic chuck 13 is a Johnson-Rahbek (JR) type, and may be 1×10e13 [Ω·cm] or more when the electrostatic chuck 13 is a coulomb type.

A diameter r1 of the disk portion 101 is formed to be slightly larger than a diameter r3 of the wafer W, and the wafer W can be accommodated in the disk portion 101. Therefore, the disk portion 101 of the tray T has a wafer placement surface for supporting the wafer W, and the tray T has a recess 103 for accommodating the wafer W. When the wafer W is placed on the wafer placement surface, a gap G (a difference between the diameter r1 and the diameter r3) generated between an outer end portion of the wafer W and an inner peripheral surface of the annular portion 102 is suitably 0.1 mm or less. In addition, it is desirable that the diameter r1 of the disk portion 101 is a size equal to or less than a diameter r4 of the support member 11 (electrostatic chuck 13) holding the tray Tw in the wafer processing module 7 in order to efficiently cool the wafer W, which will be described later.

A thickness t1 of the disk portion 101 is not particularly limited, but is desirably set to the thickness with which the wafer W can be efficiently cooled and a mechanical strength of the tray T can be ensured.

The annular portion 102 is composed of, for example, at least one material selected from Si, SiC, SiN, C, SiO2, Al2O3, Y2O3, YOF, W, Ti, TiN, ZeO2, and a green sheet, and may be composed of the same material as the material of the disk portion 101 or may be composed of a material different from the material of the disk portion 101. Therefore, the annular portion 102 may be made of a conductive material or may be made of an insulating material. However, when the annular portion 102 is used as an edge ring during the plasma processing as described later, the annular portion 102 may be made of the same material as that of the edge ring in the related art. In addition, it is desirable that the relative dielectric constant and the volume resistivity of the annular portion 102 are the same as those of the wafer W.

A thickness t2 of the annular portion 102 can be appropriately changed according to the purpose of the wafer processing. Therefore, a height of an upper surface of the annular portion 102 may be larger than, smaller than, or the same as a height of an upper surface of the wafer W. The thickness t2 of the annular portion 102 is 3 mm to 5 mm in an example. The annular portion 102 is disposed to surround the periphery of the wafer W held on the disk portion 101 during the plasma processing in the wafer processing module 7, and also functions as the edge ring (also referred to as a focus ring) for reducing the non-uniformity of the plasma processing. Therefore, the thickness t2 and a width r2 of the annular portion 102 may be configured to be substantially the same as the thickness and the width of the edge ring (not illustrated) used in the plasma processing in the related art.

A diameter of the entire tray T (that is, the outer diameter of the annular portion 102, which is the diameter r1+the width r2) may be a size equal to or larger than the diameter r4 of the support member 11 (the electrostatic chuck 13) holding the tray Tw in the wafer processing module 7 (diameter r1+width r2>diameter r4). In this case, by making the tray T large as compared to the support member 11, the front surface of the support member 11 (the electrostatic chuck 13) can be prevented from being exposed to the plasma during the plasma processing in the wafer processing module 7. Therefore, it is possible to reduce the wear of the support member 11 and to reduce the time and frequency required for the maintenance of the wafer processing module 7.

In addition, as described above, the gap G is generated between the outer end portion of the wafer W and the inner peripheral surface of the annular portion 102. In a formation portion of the gap G, the corner portion of the recess 103 may be exposed to the plasma during the plasma processing in the wafer processing module 7. In this case, depending on the material of the tray T, wear is likely to occur at the corner portion, which may cause a decrease in the life of the tray T or the generation of particles. It is found that the wear of the corner portion is likely to occur when a shape of the corner portion is a right angle.

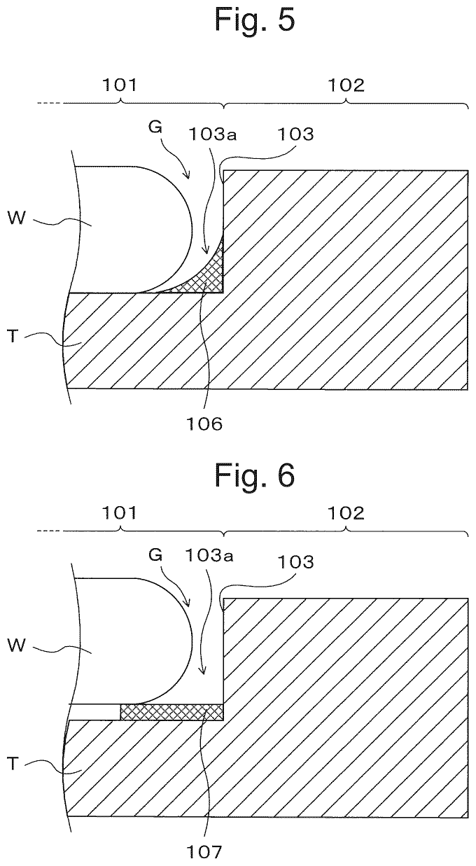

Therefore, in order to suppress wear at the corner portion of the recess 103, the shape of the corner portion may not be the right angle, and a space between the wafer W and the tray T may be filled. Specifically, for example, as illustrated in FIG. 5, it is desirable that a round-shaped spacer 106 is provided at a corner portion 103a of the recess 103. In addition, although not illustrated, a spacer configured in accordance with an outer end portion shape of the wafer W may be disposed instead of the round shape. In this case, the spacer 106 is configured of at least a member having plasma resistance. By providing the spacer 106 at the corner portion 103a in this way, during the plasma processing in the wafer processing module 7, the corner portion 103a is suppressed from being exposed to the plasma, and a decrease in the life of the tray T and the generation of particles can be suppressed.

The spacer 106 disposed at the corner portion 103a may be configured to be integrated with at least one of the disk portion 101 and the annular portion 102, which is not illustrated in the drawing, instead of being configured to be a separate body from the tray T (the disk portion 101 and the annular portion 102) as illustrated in FIG. 5.

In the examples illustrated in FIGS. 4 and 5, the wafer W is held on the disk portion 101 of the tray T, but as illustrated in FIG. 6, a step portion 107 for holding the outer peripheral portion of the wafer W may be provided in the annular portion 102, and the wafer W may be held on the step portion 107. In addition, the wafer W may be held on the spacer 106 illustrated in FIG. 5 instead of the step portion 107. In other words, the spacer 106 may have a rectangular shape in cross section and may form the step portion 107 for holding the outer peripheral portion of the wafer W.

In this case, a gap is generated between the back surface of the wafer W and the disk portion 101 of the tray T, but the gap is filled with the first heat transfer material 104 described later, so that the wafer W can be appropriately cooled as described later.

In FIG. 4, a case where the disk portion 101 and the annular portion 102 of the tray T are integrally formed using the same material is illustrated as an example, but the configuration of the tray T is not limited thereto.

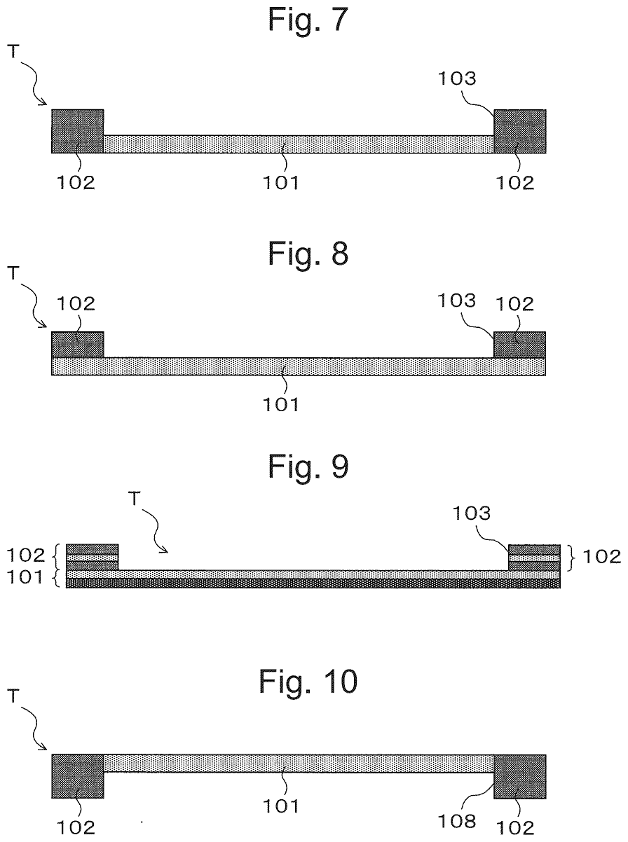

Specifically, for example, as illustrated in FIG. 4, instead of integrally configuring the disk portion 101 and the annular portion 102, the disk portion 101 and the annular portion 102 may be configured as separate bodies, and these may be bonded to each other to configure the tray T. In this case, the disk portion 101 and the annular portion 102 may be bonded to each other using, for example, a pressure-sensitive adhesive sheet or an adhesive, or may be mechanically or chemically bonded to each other. In addition, the disk portion 101 and the annular portion 102 may be made of different materials as illustrated in FIG. 7, or may be made of the same material, which is not illustrated.

In addition, in FIGS. 4 and 7, a case where the annular portion 102 surrounds the periphery of the disk portion 101, in other words, the diameter r1 of the disk portion 101 is the same as the inner diameter of the annular portion 102 is illustrated as an example. However, as illustrated in FIG. 8, the tray T may be configured in such a manner that the diameter r1 of the disk portion 101 and the outer diameter of the annular portion 102 are configured to be the same and the annular portion 102 is disposed on the upper surface of the disk portion 101. In this case, the disk portion 101 has a placement surface (ring placement surface) of the annular portion 102 as the edge ring on the upper surface. In addition, although not illustrated, even in this case, the disk portion 101 and the annular portion 102 may be made of the same material. In addition, in this case, the edge ring of the related art may be used as the annular portion 102.

In addition, in FIGS. 4, 7, and 8, the disk portion 101 and the annular portion 102 are each configured of a single member, but at least one of the disk portion 101 and the annular portion 102 may be configured of two or more members stacked as illustrated in FIG. 9. In this case, members to be stacked may be made of different materials, respectively, as illustrated in FIG. 9, and the respective members may be made of the same material, which is not illustrated.

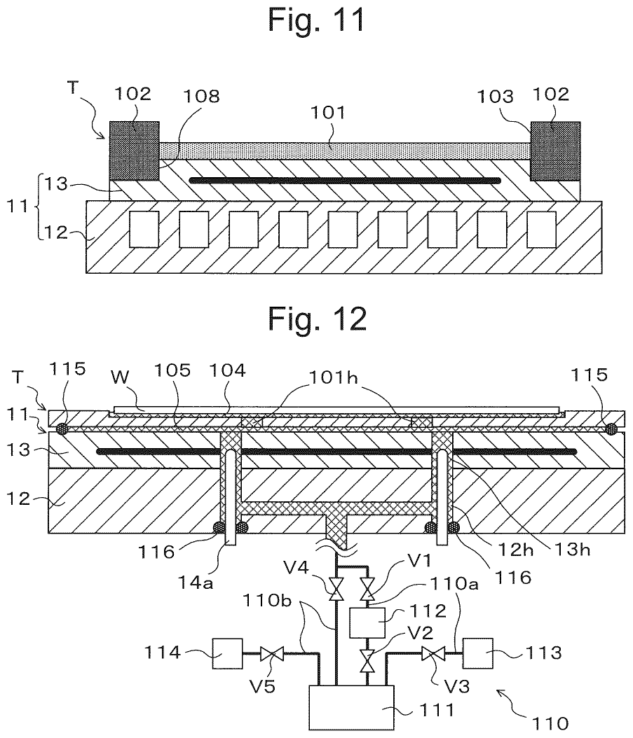

Further, in FIGS. 4 and 7 to 9, a case where the recess 103 is formed on the upper surface (wafer placement surface) side of the tray T is illustrated as an example, but instead of or in addition to this, as illustrated in FIGS. 10 and 11, a recess 108 may be further formed on the lower surface side of the tray T. In this case, it is desirable that the recess 108 formed on the lower surface side of the tray T has a shape fitted to the tray supporting surface of the electrostatic chuck 13 as illustrated in FIG. 11.

The first heat transfer material 104 is disposed between the wafer W and the wafer placement surface of the tray T as illustrated in FIG. 4. Therefore, the first heat transfer material 104 is disposed in the recess 103 of the tray T. As the first heat transfer material 104, a liquid heat transfer material or a heat transfer sheet can be adopted as described below. The wafer W placed on the tray T comes into thermal contact with the tray T on the entire surface via the first heat transfer material 104, and thus, the cooling efficiency of the wafer W by the heat transfer fluid flowing via the flow path 12a formed on the base 12 can be improved.

More specifically, in the plasma processing apparatus of the related art, in order to suppress the surface of the electrostatic chuck from being exposed to the plasma and worn, it is common that a wafer placement surface of the electrostatic chuck is made small as compared to the wafer as a holding target (diameter of wafer>outer diameter of electrostatic chuck). However, in this case, the outer peripheral portion of the wafer is not directly held by the electrostatic chuck, and as a result, there is a concern that the outer peripheral portion may be insufficiently cooled as compared to the center portion of the wafer.

In addition, for example, when deformation due to warping occurs in the wafer W, it is difficult that the electrostatic chuck comes into uniform solid contact with the wafer on the entire surface, and as a result, a pressing force against the electrostatic chuck may be weakened in a part (a portion upwardly deformed by warping) in a wafer plane, and there is a concern that cooling may be insufficient in a part in the wafer plane.

In this respect, as in the technique according to the present embodiment, by accommodating the wafer W inside the recess 103 of the tray T and further providing the first heat transfer material 104 between the wafer W and the disk portion 101 of the tray T, the wafer W and the tray T can easily come into contact with each other on the entire surface via the first heat transfer material 104, and the entire surface of the wafer W can be uniformly cooled.

As the first heat transfer material 104, a liquid heat transfer material or a sheet heat transfer material can be selected as an example. However, as long as the wafer W and the tray T appropriately come into contact with each other on the entire surface and the heat transfer efficiency between the wafer W and the tray T can be improved, a gas may be used as the first heat transfer material 104. Details of the liquid heat transfer material and the sheet heat transfer material will be described later.

The second heat transfer material 105 is disposed between the tray T and the tray placement surface of the electrostatic chuck 13 as illustrated in FIG. 4. As the second heat transfer material 105, the liquid heat transfer material or the heat transfer sheet can be adopted as described later. As the second heat transfer material 105, the same material as the first heat transfer material 104 may be used, or a different material may be used. The tray T held by the electrostatic chuck 13 comes into thermal contact with the electrostatic chuck 13 on the entire surface via the second heat transfer material 105, and thus, the cooling efficiency of the tray T by the heat transfer fluid flowing via the flow path 12a formed on the base 12, and therefore the cooling efficiency of the wafer W placed on the tray T can be improved.

More specifically, in the plasma processing apparatus of the related art, in order to sufficiently cool the wafer on the electrostatic chuck, for example, it is necessary to increase the pressing force of the wafer against the wafer placement surface of the electrostatic chuck by an electrostatic force or the like and to appropriately maintain the solid contact between the electrostatic chuck and the wafer.

In this respect, as in the technique according to the present embodiment, by providing the second heat transfer material 105 between the tray T and the tray supporting surface of the electrostatic chuck 13, the tray T and the electrostatic chuck 13 easily come into thermal contact with each other via the second heat transfer material 105, and the sufficient cooling effect of the wafer W can be expected by the weight of the tray Tw without applying stress such as electrostatic adsorption.

Although the wafer W can be cooled by the weight of the tray Tw by interposing the second heat transfer material 105 in this way, the tray T may be held on the electrostatic chuck 13 by electrostatic adsorption or the like. In this case, the pressing force of the tray T against the electrostatic chuck 13 is improved, and the cooling efficiency of the wafer W can be further increased.

The tray T according to the present embodiment is configured as described above as an example. According to the present embodiment, the annular portion 102 that functions as the edge ring in the related art as described above is transported together with the wafer W. In other words, for each wafer processing in the wafer processing module 7, the edge ring (annular portion 102) and the wafer W are carried out from the wafer processing module 7 as a single body. As a result, even when the edge ring (annular portion 102) is worn due to the plasma processing, it is not necessary to stop the operation of the wafer processing module 7 for edge ring replacement as in the related art, and for each wafer processing, the annular portion 102 carried out from the wafer processing module 7 may be replaced as it is outside the wafer processing module 7. Therefore, the operation time of the wafer processing module 7 can be maximized.

In addition, since the edge ring (annular portion 102) is replaced for each wafer processing in this way, the edge ring is prevented from being worn by the continuous wafer processing in the wafer processing module 7, and as a result, the influence of the wear of the edge ring on the process result is suppressed.

The worn tray T by the plasma processing may be carried out from the wafer processing module 7, and then a worn portion may be added and reproduced, and the wafer W may be mounted again to be transported to the wafer processing module 7. For example, the worn portion may be added and reproduced by thermal spraying, or may be added and reproduced by CVD, PVD, sol-gel, or a stacked modeling technique (3D printing technique).

Alternatively, the tray T may be subjected to rough sorting and surface blasting, sorted for each constituent material, and then may be reused as a new processed product different from the tray T. In addition, Si powder obtained by sorting may be used for the added reproduction of the worn portion of the tray T after the rough sorting.

### <Liquid Heat Transfer Material>

Next, the liquid heat transfer material used as the first heat transfer material 104 and/or the second heat transfer material will be described in detail.

When the liquid heat transfer material is used as the first heat transfer material 104 and/or the second heat transfer material 105, a material that does not volatilize at least under vacuum (depressurized) and has high thermal conductivity is selected as the liquid heat transfer material. An example of the liquid heat transfer material is a low vapor pressure liquid, and can be selected from at least one of an ionic liquid, a silicone oil (silicon liquid), and a fluorine oil.

The ionic liquid is an ionic compound that is a liquid at room temperature, and is also referred to as a room temperature molten salt. The ionic liquid has characteristics such as a vapor pressure of substantially zero and non-volatility (not volatilizing even at a high temperature or in a vacuum). The ionic liquid is composed of positive ions (cations) and negative ions (anions).

As the positive ions constituting the ionic liquid, for example, positive ions such as a pyridinium type, an imidazolium type, an ammonium type, a pyrrolidinium type, and a piperidinium type, each of which contains nitrogen, and a phosphonium type containing phosphorus are provided. These positive ions include an alkyl group [—(CH2)nCH3] or the like as a side chain. In addition, as the positive ions constituting the ionic liquid, for example, a morphonium type and a sulfonium type are also provided.

As the negative ions constituting the ionic liquid, TfO—, Tf2N-(TFSA-), Tf3C—, FSA-, CH3COO—, CF3COO—, BF4-, PF6-, (CN)2N—, AlCl4-, Al2Cl7-, and the like are provided, but the negative ions are not limited thereto. In addition, as the negative ions constituting the ionic liquid, PF6- and Cl— are also provided.

As specific examples of the ionic liquid, potassium bis(trifluoromethanesulfonyl)imide, potassium bis(nonafluorobutanesulfonyl)imide, 1-ethyl-3-methylimidazolium bis(trifluoromethanesulfonyl)imide, 1-methyl-1-propylpyrrolidinium bis(trifluoromethanesulfonyl)imide, 1-butyl-3-methylimidazolium bis(trifluoromethanesulfonyl)imide, and the like are provided.

Next, an example of a supplying method of the liquid heat transfer material as the first heat transfer material 104 and the second heat transfer material 105 will be described. FIG. 12 is a cross-sectional view illustrating an example of a configuration of the support member 11 when the liquid heat transfer material is supplied inside the wafer processing module 7. In FIG. 12, the flow path 12a formed in the base 12 is omitted for simplicity of illustration.

When the liquid heat transfer material is supplied inside the wafer processing module 7, for example, the through-holes 12h and 13h formed in the support member 11 can be used. That is, as illustrated in FIG. 12 as an example, a liquid supply 110 is connected to the through-holes 12h and 13h formed in the base 12 and the electrostatic chuck 13 of the support member 11, respectively, whereby the liquid heat transfer material (second heat transfer material 105) can be supplied to the lower surface side of the tray T via the through-holes 12h and 13h. In addition, in this case, by forming a through-hole 101h for supplying the liquid in the disk portion 101 of the tray T, the liquid heat transfer material (first heat transfer material 104) can be supplied to the inside of the tray T. Since the through-hole 101h does not hinder the delivery of the tray Tw by the lift pin 14a, it is desirable that the through-hole 101h is formed to be deviated from a through-hole 13h in a circumferential direction and/or a radial direction.

The liquid supply 110 has a liquid supply source 111, a flow rate controller 112, a pressurizing mechanism 113, and a depressurizing mechanism 114. In addition, the liquid supply 110 has a liquid supply path 110a and a liquid discharge path 110b, and the flow rate controller 112 and the pressurizing mechanism 113 are disposed in the liquid supply path 110a, and the depressurizing mechanism 114 is disposed in the liquid discharge path 110b, respectively. In addition, valves V1 to V5 for controlling the flow of the liquid heat transfer material are disposed in the liquid supply path 110a and the liquid discharge path 110b.

The liquid supply source 111 stores the liquid heat transfer material (the first heat transfer material 104 and/or the second heat transfer material 105) supplied toward the tray T.

The flow rate controller 112 controls the flow rate of the liquid heat transfer material supplied toward the tray T.

The pressurizing mechanism 113 supplies an inert gas (for example, an N2 gas) toward the liquid supply source 111, and thereby the liquid heat transfer material stored in the liquid supply source 111 is sent toward the tray T.

The depressurizing mechanism 114 depressurizes the inside of the liquid supply source 111, and thereby the liquid heat transfer material supplied toward the tray T is collected in the liquid supply source 111.

The valves V1, V2, and V3 are disposed on a liquid supply path 110a side. Specifically, the valves V1 and V2 are disposed on an upstream side and a downstream side of the flow rate controller 112, respectively, and the valve V3 is disposed in the vicinity of the pressurizing mechanism 113.

The valves V4 and V5 are disposed on a liquid discharge path 110b side. Specifically, the valve V4 is disposed in the vicinity of the liquid supply source 111, and the valve V5 is disposed in the vicinity of the depressurizing mechanism 114 in the liquid discharge path 110b.

In addition, when the liquid heat transfer material is used as the first heat transfer material 104 and the second heat transfer material 105, a sealing member for preventing leakage of the liquid heat transfer material is disposed in the support member 11. Specifically, as illustrated in FIG. 12, at least a first sealing member 115 for preventing leakage to an outer peripheral side of the support member 11 from an interface between the tray T and the electrostatic chuck 13, and a second sealing member 116 for preventing leakage downward of the support member 11 via the through-hole 12h are disposed. As the sealing member, for example, an O-ring made of FKM or FFKM can be used.

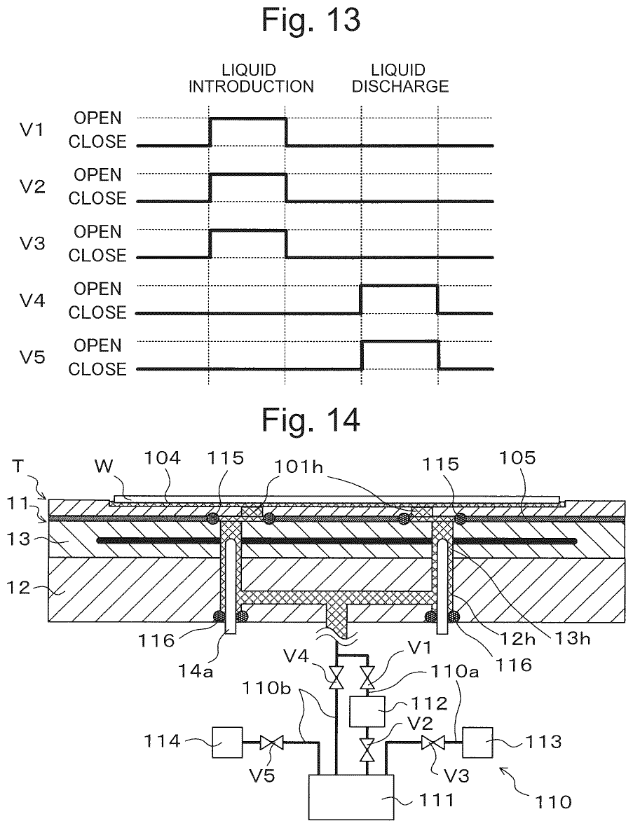

FIG. 13 is a sequence diagram illustrating operations of the valves V1 to V5 when the liquid supply 110 configured as described above supplies/discharges the liquid heat transfer material.

As illustrated in FIG. 13, when the liquid heat transfer material is supplied toward the tray T in the wafer processing, the valves V1 to V3 on the liquid supply path 110a side are opened, and the valves V4 and V5 on the liquid discharge path 110b side are closed. Then, as the liquid supply source 111 is pressurized by the pressurizing mechanism 113, the liquid heat transfer material in the liquid supply source 111 is supplied to the flow rate controller 112. The liquid heat transfer material of which the flow rate is controlled by the flow rate controller 112 is then supplied to the lower surface side of the tray T as the second heat transfer material 105 via the through-holes 12h and 13h, and is supplied to the inside of the tray T as the first heat transfer material 104 via the through-hole 101h.

On the other hand, when the liquid heat transfer material supplied to the tray T is collected when the tray is carried out, the valves V4 and V5 on the liquid discharge path 110b side are opened, and the valves V1 to V3 on the liquid supply path 110a side are closed. Then, as the liquid supply source 111 is depressurized by the depressurizing mechanism 114, the first heat transfer material 104 is collected in the liquid supply source 111 via the through-hole 101h, the lower surface side of the tray T, and the through-holes 12h and 13h, and the second heat transfer material 105 is collected in the liquid supply source 111 via the through-holes 12h and 13h.

The supply of the liquid heat transfer material as the first heat transfer material 104 and/or the second heat transfer material 105 to the tray T is performed as described above. As described above, by supplying the liquid heat transfer material using the through-holes 12h and 13h of the lift pin 14a for lifting and lowering the existing tray T, it is not necessary to form a new through-hole for supplying the liquid heat transfer material in the support member 11, and the supply/discharge of the liquid heat transfer material can be efficiently performed.

In FIG. 12, a case where the liquid heat transfer material is supplied to both the inside (the first heat transfer material 104) of the tray T and the lower portion (the second heat transfer material 105) of the tray T from the liquid supply source 111 is illustrated as an example, but the liquid heat transfer material supplied from the liquid supply source 111 may be one of the inside of the tray T and the lower portion of the tray T.

For example, when the liquid supply source 111 supplies the liquid heat transfer material only to the inside (the first heat transfer material 104) of the tray T (for example, when the second heat transfer material 105 is the heat transfer sheet described below), as illustrated in FIG. 14, the first sealing member 115 is disposed at least to surround peripheries of the through-hole 13h and the through-hole 101h. In this case, in order to supply the liquid heat transfer material only to the inside of the tray T, the heat transfer sheet is not disposed in a part between the tray T and the tray placement surface of the electrostatic chuck 13.

In addition, for example, when the liquid heat transfer material is supplied only to the lower surface side (the second heat transfer material 105) of the tray T from the liquid supply source 111 (for example, when the first heat transfer material 104 is the heat transfer sheet described below), the disposition of the first sealing member 115 is not changed from that in FIG. 12, and the through-hole 101h may not be formed in the disk portion 101 of the tray T.

As described above, even when the liquid heat transfer material is supplied only to either the inside (the first heat transfer material 104) of the tray T or the lower portion (the second heat transfer material 105) of the tray T from the liquid supply source 111, the supply and discharge of the liquid heat transfer material can be efficiently performed by supplying the liquid heat transfer material using the through-holes 12h and 13h for lifting and lowering the tray T.

In the examples illustrated in FIGS. 12 and 14, the first heat transfer material 104 and/or the second heat transfer material 105 as the liquid heat transfer material is supplied inside the wafer processing module 7, but at least the first heat transfer material 104 inside the tray T may be supplied in advance outside the wafer processing module 7.

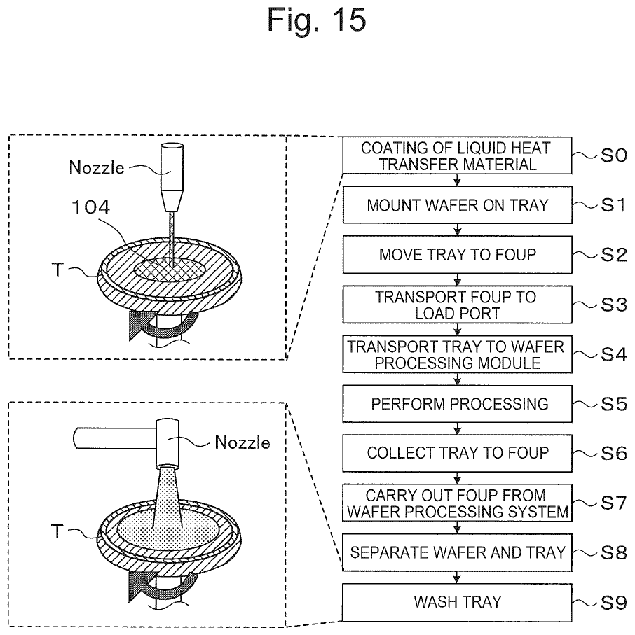

Specifically, as illustrated in a flowchart of FIG. 15, before the wafer W is mounted on the tray T, the liquid heat transfer material (the first heat transfer material 104) is supplied to the recess 103 of the tray T in a coating apparatus (not illustrated) (step S0 of FIG. 15). A supplying method of the liquid heat transfer material to the tray T is not particularly limited. For example, as illustrated in FIG. 15, the liquid heat transfer material may be supplied by so-called spin coating in which the liquid heat transfer material is supplied from a nozzle disposed above the tray T while the tray T is rotated. Thereafter, the tray T to which the liquid heat transfer material is supplied is subjected to various transport/processing by the same method as the flow illustrated in FIG. 3.

In addition, the tray T is subjected to all types of the processing and separated from the wafer W, and then the recess 103 is washed in a washing apparatus (not illustrated) and the first heat transfer material 104 is removed. A washing method of the tray is not particularly limited, and for example, as illustrated in FIG. 15, so-called spin washing may be performed in which a washing liquid is supplied from the nozzle disposed above the tray T while rotating the tray T.

The coating apparatus supplying the liquid heat transfer material to the tray T and the washing apparatus washing the tray T may be provided inside or outside the wafer processing system 1, as in the above-described mounting apparatus (not illustrated) or separation apparatus (not illustrated). Therefore, the supply of the liquid heat transfer material (the first heat transfer material 104) to the tray T may be performed inside or outside the wafer processing system 1.

As described above, by using the liquid heat transfer material as the first heat transfer material 104, the entire surface of the wafer W and the entire surface of the tray T can appropriately come into thermal contact with each other via the liquid heat transfer material. Therefore, the heat transfer efficiency between the wafer W and the tray T can be improved. In addition, by using the liquid heat transfer material as the second heat transfer material 105, the entire surface of the tray T and the entire surface of the electrostatic chuck 13 can appropriately come into thermal contact with each other via the liquid heat transfer material. Therefore, the heat transfer efficiency between the tray T and the electrostatic chuck 13 can be improved, and thus the heat transfer efficiency between the wafer W and the electrostatic chuck 13 can be improved. As a result, the entire surface of the wafer W can be appropriately cooled by the heat transfer fluid flowing the inside of the base 12.

In the example illustrated in FIG. 14, the through-holes 12h and 13h for the lift pin 14a formed in advance in the support member 11 are used as the flow path for supplying the liquid heat transfer material. However, it goes without saying that new through-holes (not illustrated) for supplying the liquid heat transfer material may be formed in the support member 11.

### <Sheet Heat Transfer Material>

Next, details of the sheet heat transfer material used as the first heat transfer material 104 and/or the second heat transfer material 105 will be described.

When the sheet heat transfer material is used as the first heat transfer material 104 and/or the second heat transfer material 105, a material that does not deteriorate at least under vacuum (depressurized) and has high thermal conductivity and plasma resistance is selected as the sheet heat transfer material. A thickness of the sheet heat transfer material may be less than 100 μm in an example. An example of the sheet heat transfer material includes a Si-containing material, a SiC-containing material, a W-containing material, an Al2O3-containing material, an AlN-containing material, a nano SiC-containing material, a diamond powder-containing material, a CNT-containing material, a fluorine rubber-based sheet, a silicone sheet, an acrylic sheet, a mesh sheet impregnated with the above-described liquid heat transfer material, or the like. In addition, when the fluorine rubber-based sheet, the silicone sheet, or the acrylic sheet described above is used as the sheet heat transfer material as the first heat transfer material 104, it is desirable that the sheet heat transfer material has ultraviolet (UV) curability as described later. In addition, it is desirable that the sheet heat transfer material as the first heat transfer material 104 has thermoplasticity as described later.

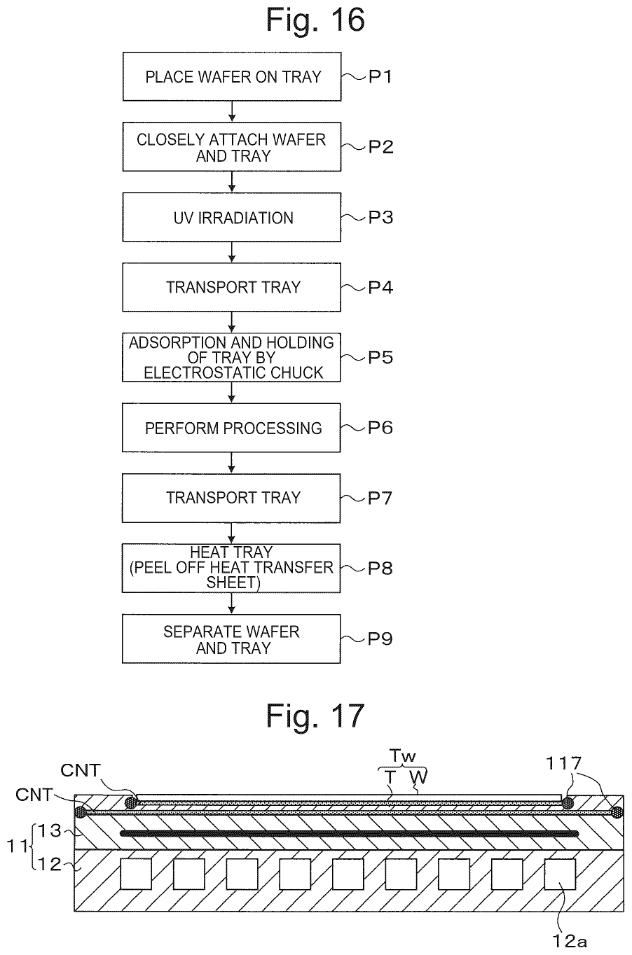

FIG. 16 is a diagram illustrating main steps of the wafer processing when the sheet heat transfer material is used as the first heat transfer material 104. In the following description, a case where the sheet heat transfer material as the first heat transfer material 104 has UV curability and thermoplasticity will be described as an example. In addition, in the following description, the type of the second heat transfer material 105 is not particularly limited.

First, before the wafer processing in the wafer processing module 7, the wafer W as a processing target is placed on the tray T by a mounting apparatus (not illustrated) provided outside or inside the wafer processing system 1 (step P1 in FIG. 16). In this case, the sheet heat transfer material as the first heat transfer material 104 is disposed in advance in the recess 103 of the tray T on which the wafer W is placed. Therefore, the wafer W is placed on the disk portion 101 of the tray T via the first heat transfer material 104.

When the wafer W is placed on the tray T, subsequently, the wafer W and the tray T come into close contact with each other on the entire surface (step P2 in FIG. 16). Specifically, for example, an electrostatic adsorption voltage is applied to a stage holding the tray T to improve the pressing force of the wafer W against the tray T by a Coulomb force.

When the contact force (the pressing force of the wafer W against the tray T) between the wafer W and the tray T can be improved, the operation of step P2 is not particularly limited. For example, a vacuum force or the like may be used, or the tray T and the wafer W may be physically pressed.

Next, in a state where the wafer W and the tray T come into contact with each other on the entire surface, the UV is irradiated to the first heat transfer material 104 interposed between the wafer W and the tray T (step P3 in FIG. 16). Then, the first heat transfer material 104 is cured due to the influence of the UV irradiation, and the wafer W and the tray T are maintained in a state of coming into close contact with each other without applying the Coulomb force or the like. In addition, as a result, the adhesion between the tray T and the wafer W in the mounting apparatus (not illustrated) is completed, and the tray Tw on which the wafer W is mounted is prepared.

Next, the tray Tw on which the wafer W is mounted is transported to the wafer processing module 7 (step P4 in FIG. 16). In addition, the tray Tw transported to the wafer processing module 7 is adsorbed and held on the electrostatic chuck 13 of the support member 11 via the second heat transfer material 105 (step P5 in FIG. 16).

In the wafer processing module 7, any processing according to the purpose of the wafer processing, for example, the plasma processing such as etching is performed (step P6 in FIG. 16). Specifically, for example, after the wafer W is carried in, the inside of the plasma processing chamber 10 is depressurized to a desired degree of vacuum, and then a desired processing gas is supplied to the plasma processing space 10s. Thereafter, at least one RF signal (RF power) is supplied to at least one lower electrode and/or at least one upper electrode by the RF power supply 31, and the processing gas is excited to form the plasma. Then, the wafer W is subjected to the plasma processing by the action of the plasma formed in this manner. In this case, the plasma processing of the wafer W is performed in a state where the wafer W is placed on the tray T.

In this case, the wafer W and the tray T come into contact with each other on the entire surface via the first heat transfer material 104, and the tray T and the electrostatic chuck 13 come into contact with each other on the entire surface via the second heat transfer material 105. As a result, the entire surface of the wafer W is appropriately thermally connected to the electrostatic chuck 13, and the cooling of the wafer W by the heat transfer fluid flowing through the inside of the base 12 is efficiently performed.

When the desired wafer processing is performed on the tray Tw (the wafer W), the tray Tw is then transported to the separation apparatus (not illustrated) provided outside or inside the wafer processing system 1 (step P7 in FIG. 16).

In the separation apparatus, the tray Tw on the stage is heated (step P8 in FIG. 16). Then, the first heat transfer material 104 having thermoplasticity is softened, and the wafer W is peeled off from the tray T. Thereafter, when the wafer W peeled off from the tray T is completely separated from the tray T (step P9 in FIG. 16), a series of wafer processing using the wafer processing system 1 is ended.

As described above, by using the sheet heat transfer material as the first heat transfer material 104, the entire surface of the wafer W and the entire surface of the tray T can appropriately come into thermal contact with each other on the entire surface via the sheet heat transfer material, and the cooling efficiency of the wafer W can be improved. In this case, since the sheet heat transfer material has UV curability, the sheet heat transfer material is cured in a state where the wafer W is pressed against the tray T with a surface pressure applied thereto (in a state of coming into contact with each other on the entire surface), and thus even after the surface pressure is released, the entire surface contact between the tray T and the wafer W can be appropriately maintained, and the cooling efficiency of the wafer W can be further improved. In addition, in this case, since the sheet heat transfer material has thermoplasticity, the wafer W can be easily peeled off from the tray T by heating the cured sheet heat transfer material.

Further, by using the sheet heat transfer material as the second heat transfer material 105, the entire surface of the tray T and the entire surface of the electrostatic chuck 13 can appropriately come into thermal contact with each other on the entire surface via the sheet heat transfer material, and the cooling efficiency of the wafer W can be further improved.

In addition, as described above, by adhering the wafer W and the tray T with the sheet heat transfer material having UV curability, it is not necessary to apply a voltage for electrostatic adsorption for absorbing the warping of the wafer W during the process in the wafer processing module 7. Therefore, as described above, it is possible to achieve energy saving by omitting the application of the electrostatic voltage while improving the cooling efficiency of the wafer W with high heat transfer, and to simplify the apparatus configuration.

### <Other Heat Transfer Materials>

In the above description, a case where the liquid heat transfer material or the sheet heat transfer material is used as the first heat transfer material 104 and the second heat transfer material 105 is described as an example. However, when the first heat transfer material 104 and the second heat transfer material 105 are newly provided by being externally attached to the tray T as described above, the number of interfaces between the wafer W and the base 12 may increase, and a synthesized thermal resistance for cooling the wafer W by the heat transfer fluid flowing through the flow path 12a may increase, as compared to a case where the wafer W is adsorbed and held on the electrostatic chuck 13 as in the related art.

Therefore, in the tray T according to the present embodiment, instead of or in addition to the external attachment of the first heat transfer material 104 and the second heat transfer material 105 as described above, as illustrated in FIG. 17, a carbon nanotube (CNT) as a heat transfer layer may be synthesized on the surface of the tray T (the recess 103 and the lower surface side of the tray T).

According to the present embodiment, it is not necessary to apply the electrostatic adsorption voltage to the support member 11 in the related art in order to reduce the synthesized thermal resistance, and efficient high heat transfer can be exhibited only by causing the CNT to come into contact with the electrostatic chuck 13. In addition, with the present configuration, it is possible to reduce the interfacial thermal resistance generated in the tray structure according to the present embodiment, and to realize the reduction or power down of the electrostatic electrode for applying the electrostatic adsorption voltage, thereby simplifying the structure around the lower electrode.

The CNT synthesized in the tray T in this way is particularly likely to react with an O (oxygen)-based plasma, and may be worn in the plasma processing in the wafer processing module 7, which may cause particle generation.

Therefore, when the CNT is synthesized on the surface of the tray T in this way, a sealing member 117 for protecting the CNT from the plasma may be disposed. As a material of the sealing member 117, FKM or FFKM can be used.

The heat transfer layer synthesized on the surface of the tray T (the recess 103 and the lower surface side of the tray T) is not limited to CNT, and can be appropriately selected as long as it is a material that can be synthesized on the tray T and can improve the heat transfer performance, such as nano SiC, a diamond film, and a sol-gel film.

### <Mounting/Separating Method of Wafer on Tray>

Next, an example of a mounting method of the wafer W on the tray T in the above-described mounting apparatus (not illustrated) and a separating method of the wafer W from the tray T in the separation apparatus (not illustrated) will be described.

### (1) Use of Lift Pin

In a case of mounting/separating the wafer W with respect to the tray T, the through-hole 101h formed in the disk portion 101 illustrated in FIG. 12 can be used.

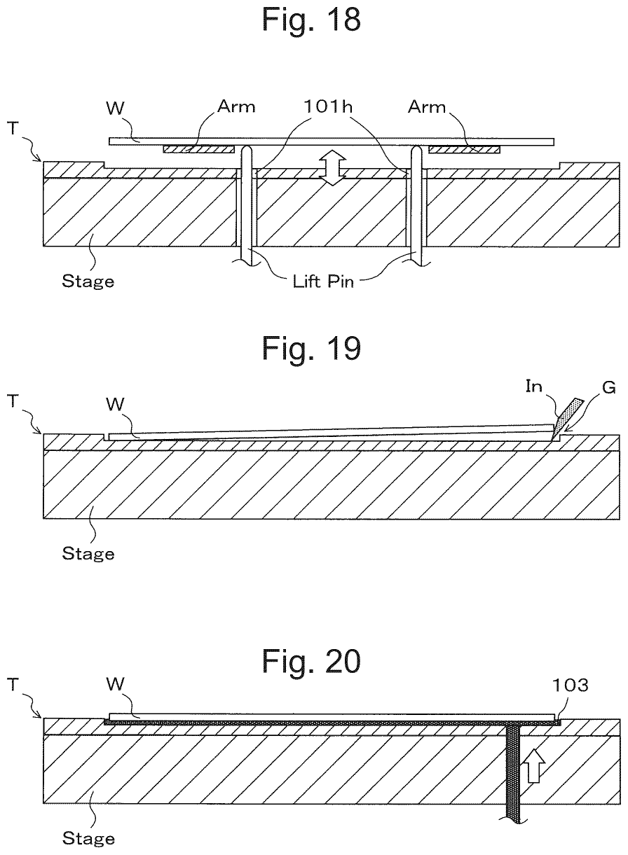

That is, as illustrated in FIG. 18, in the mounting apparatus/separation apparatus, in a state where the tray T is placed on the stage, the lift pin is configured to be protrudable and retractable from the upper surface of the disk portion 101 via the through-hole 101h formed in the disk portion 101 of the tray T. Accordingly, the lower surface of the wafer W mounted on the tray T can be supported by the lift pin and moved in the vertical direction (lift-up), and the mounting/separation of the wafer W with respect to the tray T can be realized.

The transport of the wafer W between the mounting apparatus/separation apparatus and the outside is performed, for example, by holding the wafer W by a transport mechanism provided on the outside of the mounting apparatus/separation apparatus. In this case, in order to suppress the damage to the device layer formed on the front surface side of the wafer W, the transport mechanism holds the back surface side of the wafer W opposite to the surface on which the device layer is formed or the outer end portion of the wafer W. For example, when the transport mechanism holds the back surface of the wafer W, as illustrated in FIG. 18, the wafer W is configured to be insertable between the wafer W and the stage in a state where the wafer W is lifted up by the lift pin.

### (2) Use of Insertion Member

In a case of separating the wafer W from the tray T, an insertion member insertable into the gap G (see FIG. 4) formed between the annular portion 102 of the tray T and the wafer W may be used.

Specifically, when separating the wafer W from the tray T, as illustrated in FIG. 19, the wafer W and an insertion member In for separating from the tray T may be inserted into the gap G, and the wafer W may be pressed up by the insertion member In to peel off the wafer W and the tray T. The wafer W peeled off from the tray T by the insertion member In is carried out from the separation apparatus, for example, by the transport mechanism holding the back surface or the outer end portion.

The insertion member In may be inserted into only one place of the gap G, or may be inserted into multiple places of the gap G in the circumferential direction. In this case, the insertion member In may have one insertion portion and the insertion portion may be continuously inserted into the multiple places of the gap G, or the insertion member In may have multiple insertion portions and the multiple insertion portions may be simultaneously inserted into the multiple places of the gap G.

### (3) Use of Fluid

When separating the wafer W from the tray T, a fluid may be introduced between the wafer W and the tray T, that is, into the recess 103 instead of or in addition to the lift pin or the insertion member In.

Specifically, as illustrated in FIG. 20, in the separation apparatus, the fluid is supplied between the wafer W and the tray T via the through-hole formed in the stage and the through-hole 101h formed in the disk portion 101 of the tray T, thereby bringing the wafer W into a state of floating from the tray T. In such a state, the lift pin or the insertion member In illustrated in FIGS. 18 and 19 is used, whereby the tray T and the wafer W can be easily separated. Alternatively, the wafer W can be carried out from the separation apparatus by holding the outer end portion of the wafer W by the transport mechanism in such a state.

As the fluid supplied to the recess 103, an inert gas (for example, N2 gas) or the above-mentioned ionic liquid can be used.

### (4) Division of Tray

When mounting/separating the wafer W with respect to the tray T, at least a part of the tray T may be divided, and the wafer W may be configured to be carried in/out with respect to the recess 103 of the tray T from the divided portion.

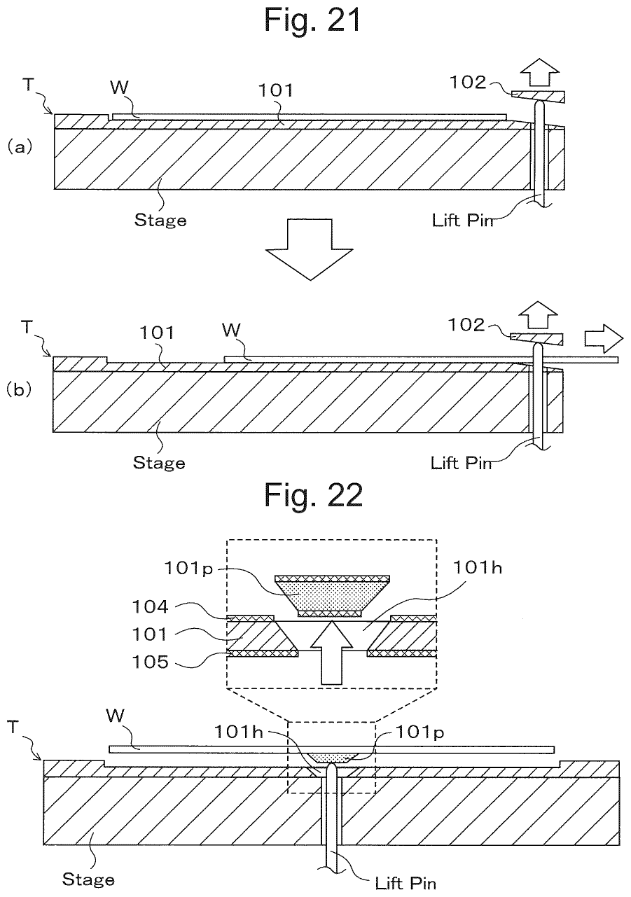

Specifically, for example, as illustrated in FIG. 21(a), a part or all of the annular portion 102 of the tray T may be configured to be divided with respect to the disk portion 101 to be movable (lift-up) in the vertical direction. In other words, a part of the tray T (particularly, the annular portion 102) may be divided and configured.

Then, a divided portion 102 is lifted up, and in such a state, the wafer W is slid and moved with respect to the recess 103 as illustrated in FIG. 21(b), so that the wafer W can be mounted on and separated from the tray T.

### (5) Other Division Methods of Tray

In the example of (4) described above, a part of the annular portion 102 of the tray T is divided, but at least a part of the disk portion 101 may be divided instead of the annular portion 102.

Specifically, for example, as illustrated in FIG. 22, a part or all of the disk portion 101 of the tray T may be configured to be divided so as to be capable of being driven by the buffer (lift-up) in the vertical direction. In other words, a part of the tray T (particularly, the disk portion 101) may be configured by being divided.

Then, a divided portion 101p is lifted up by the lift pin, and in such a state, a transport arm of the transport mechanism provided outside the mounting apparatus/separation apparatus is inserted into the back surface side of the wafer W, whereby the wafer W can be mounted/separated with respect to the tray T.

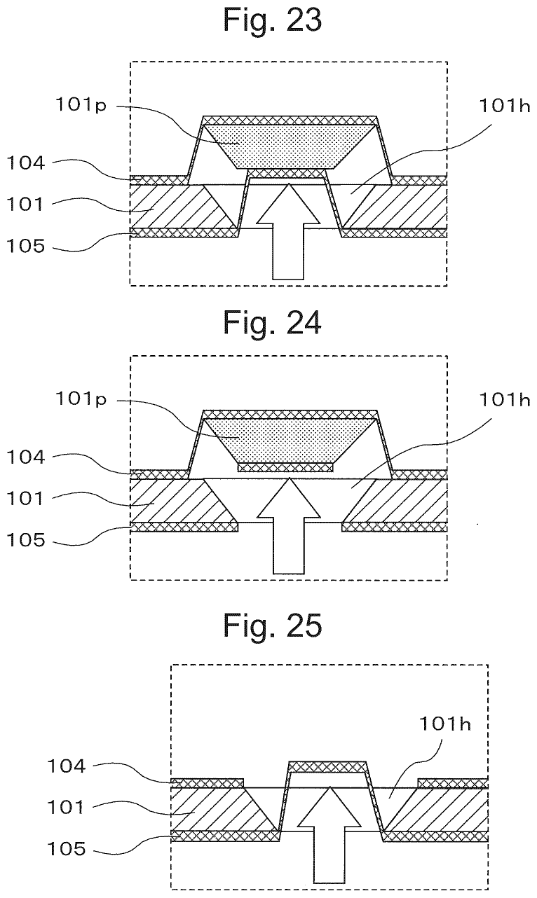

When a part of the disk portion 101 of the tray T is formed by being divided in this way, it is desirable that the sheet heat transfer material is selected as the first heat transfer material 104 and the second heat transfer material 105 described above, instead of the liquid heat transfer material, in order to prevent leakage during lift-up of the divided portion 101p. When the sheet heat transfer material is selected as the first heat transfer material 104 and the second heat transfer material 105, the first heat transfer material 104 and the second heat transfer material 105 may be divided according to a shape of the divided portion 101p of the disk portion 101 as illustrated in FIG. 22. Alternatively, the first heat transfer material 104 and the second heat transfer material 105 may not be divided, and a stretchable sheet heat transfer material may be selected to stretch and contract in the vertical direction in accordance with the lift-up of the divided portion 101p as illustrated in FIG. 23. Further, for example, as illustrated in FIG. 24, only one of the first heat transfer material 104 and the second heat transfer material 105 may be divided in accordance with the shape of the divided portion 101p (in the example illustrated in the drawing, the second heat transfer material 105).

Further, for example, in the example illustrated in FIGS. 22 to 24, a part of the disk portion 101 is divided and configured to be lifted up as the divided portion 101p. However, as illustrated in FIG. 25, the through-hole 101h into which the lift pin is inserted may be formed in a part or all of the disk portion 101, and the wafer W may be lifted up by the lift pin via the first heat transfer material 104 or the second heat transfer material 105 (in the example illustrated in the drawing, the second heat transfer material 105). Therefore, the through-hole 101h formed in the disk portion 101 of the tray T may be provided with the divided portion 101p capable of being driven by the buffer, or the divided portion 101p may be omitted.

In the examples illustrated in FIGS. 22 to 25, the through-hole 101h (the divided portion 101p) for mounting/separating the wafer W with respect to the tray T is disposed only at one center of the disk portion 101, but the number of through-holes 101h (the divided portion 101p) is not limited thereto, and the through-holes 101h (the divided portion 101p) may be disposed at multiple in-plane portions (preferably three or more portions) of the disk portion 101.

In addition, the shape of the through-hole 101h (the divided portion 101p) is not particularly limited, and any shape such as a circular shape or a rectangular shape in plan view can be selected.

### <Transporting/Placing Method of Tray on Electrostatic Chuck>

Next, a transporting/placing method of the tray Tw configured as described above on the electrostatic chuck 13 in the wafer processing module 7 will be described.

### (1) Use of Lift Pin

When the tray Tw is placed on the tray supporting surface of the electrostatic chuck 13, the lift pin 14a inserted into the through-holes 12h and 13h can be used.

That is, for example, in a state where the tray Tw is disposed above the electrostatic chuck 13 by the second transport mechanism 8 (see also FIG. 3), the lift pin 14a is made to protrude from the upper surface of the electrostatic chuck 13 via the through-holes 12h and 13h, whereby the tray Tw is delivered from the second transport mechanism 8 to the upper end portion of the lift pin 14a. Thereafter, after the second transport mechanism 8 is retracted, the lift pin 14a is lowered, whereby the tray Tw can be delivered from the lift pin 14a onto the tray supporting surface of the electrostatic chuck 13.

As described above, by supporting the lower surface side of the tray Tw and performing transport/delivery by the second transport mechanism 8 and the lift pin 14a, the tray Tw can be delivered on the electrostatic chuck 13 without damaging the device layer formed on the surface of the wafer W mounted on the tray T.

(2) Holding of Tray from Upper/Side Surface

When transporting the wafer W to the electrostatic chuck 13, it is necessary to prevent damage to the device layer formed on the surface of the wafer W in this manner, and in the wafer processing in the related art without using the tray T, it is necessary to hold the back surface side of the wafer W in principle and to perform transportation/delivery.

In this regard, in the wafer processing according to the present embodiment, the wafer W is transported/delivered in a state of being mounted on the tray T as described above. In addition, in the present embodiment, the tray T has the annular portion 102 having a circular shape disposed on a radially outer side of the wafer W.

Therefore, in the wafer processing according to the present embodiment, instead of supporting the lower surface side of the tray Tw by the second transport mechanism 8 and the lift pin 14a as described above, the tray T may be held from the upper side or the side surface side, and the transport/delivery may be performed between the tray T and the electrostatic chuck 13.

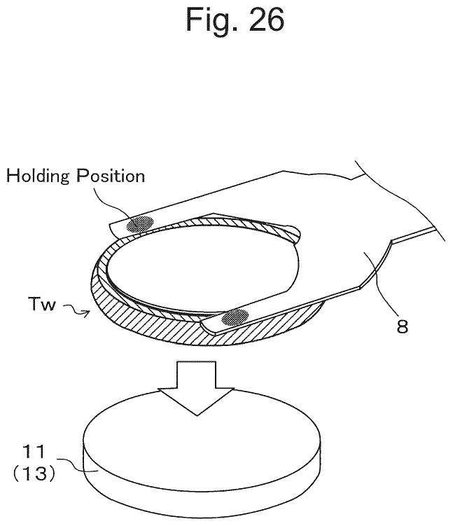

Specifically, as illustrated in FIG. 26 as an example, for example, the annular portion 102 of the tray T on which the wafer W is mounted may be held and transported by the second transport mechanism 8 from the upper side. In this case, by holding the annular portion 102 of the tray T, damage to the device layer formed on the surface of the wafer W is suppressed. Therefore, the second transport mechanism 8 may physically hold and transport the annular portion 102 of the tray T. The holding method of the tray T by the second transport mechanism 8 is not particularly limited, and any method such as a magnet, vacuum adsorption, or electrostatic adsorption can be selected.

As described above, in the wafer processing according to the present embodiment in which the wafer W as a processing target is mounted on the tray T and is transported/delivered, since it is not necessary to cause the wafer W and the second transport mechanism 8 to come into direct contact with each other by holding the tray T, the tray Tw on which the wafer W is mounted can be accessed from above and can be held/transported.

In addition, since the tray Tw can be held from above in this way, when delivering the tray Tw to the electrostatic chuck 13, it is not necessary to use the lift pin 14a as in the related art, and the tray Tw can be delivered directly from the second transport mechanism 8 to the electrostatic chuck 13. Therefore, when the tray Tw is held from above or from the side, the lifter 14 for delivering the tray Tw to the electrostatic chuck 13 is omitted, and the configuration of the wafer processing module 7 can be simplified.

### <Fixing Method of Tray to Support Member>

Next, an example of a fixing method of the tray Tw transported as described above to the support member 11 (the electrostatic chuck 13) in the wafer processing module 7 will be described.

As described above, the tray Tw is held on the tray supporting surface of the support member 11, but in order to efficiently cool the wafer W by the heat transfer fluid flowing through the flow path 12a formed in the base 12, it is necessary to increase the pressing force (surface pressure) of the tray Tw against the electrostatic chuck 13. Therefore, in the following description, in order to increase the cooling efficiency of the wafer W, a holding method of the tray Tw by the electrostatic chuck 13 with a pressing force equal to or greater than the weight of the tray Tw will be described.

### (1) Electrostatic Adsorption

As illustrated in FIG. 2, the electrostatic chuck 13 of the support member 11 is provided with the electrostatic electrode 13b for supporting the tray Tw on the tray supporting surface. The support member 11 can be adsorbed and held to the tray Tw by using the electrostatic electrode 13b.

First, a case where the disk portion 101 of the tray T is made of a conductive material will be described.

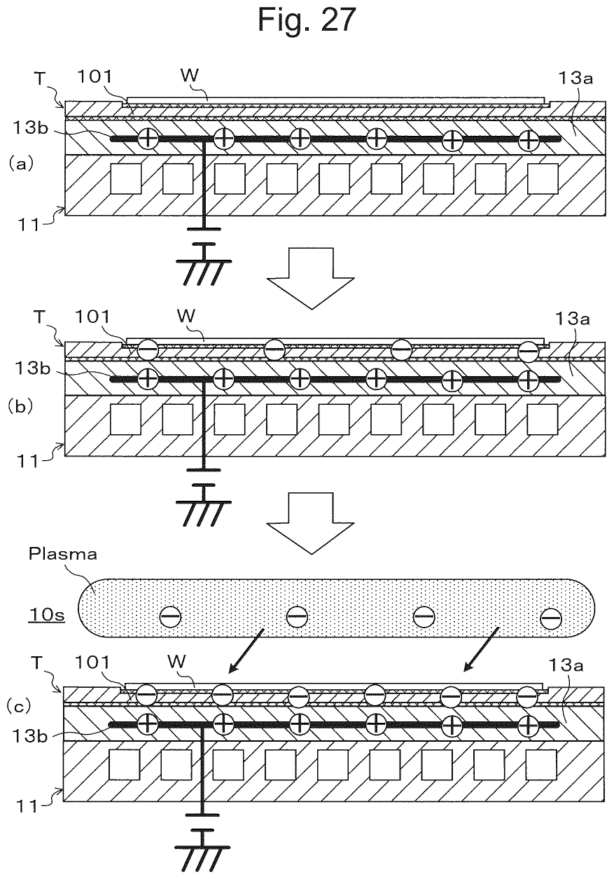

When adsorbing and holding the tray T, first, as illustrated in FIG. 27(a), a voltage (positive (+) charge in the example illustrated in the drawing) is applied to the electrostatic electrode 13b. Then, the electrostatic electrode 13b is positively (+) charged.

When the electrostatic electrode 13b is positively (+) charged, as illustrated in FIG. 27(b), an electric charge having a polarity (that is, a negative (−)) opposite to the electric charge accumulated in the electrostatic electrode 13b is accumulated on the disk portion 101 of the tray T or the wafer W with the ceramic member 13a as a dielectric interposed therebetween. Then, a Coulomb force is generated in which the tray T (the wafer W) and the electrostatic electrode 13b are both polarities, and thus the tray Tw is adsorbed and held on the tray supporting surface of the electrostatic chuck 13.

In addition, when the tray Tw is adsorbed and held by the electrostatic chuck 13 by the Coulomb force in this way, the Coulomb force can be increased by forming the plasma in the wafer processing module 7, and the adsorption holding force of the electrostatic chuck 13 can be increased. Specifically, as illustrated in FIG. 27(c), by forming the plasma in the plasma processing space 10s, the charge having the polarity opposite to the charge accumulated in the electrostatic electrode 13b (that is, the negative (−)) is moved from the plasma to the disk portion 101 of the tray T or the wafer W. That is, the Coulomb force can be increased by supplementing the charge from the plasma, and the tray Tw can be more firmly adsorbed and held.

Next, a case where the disk portion 101 of the tray T is made of an insulating material will be described. When the disk portion 101 of the tray T is made of the insulating material, a charging electrode 101b is disposed inside the disk portion 101.

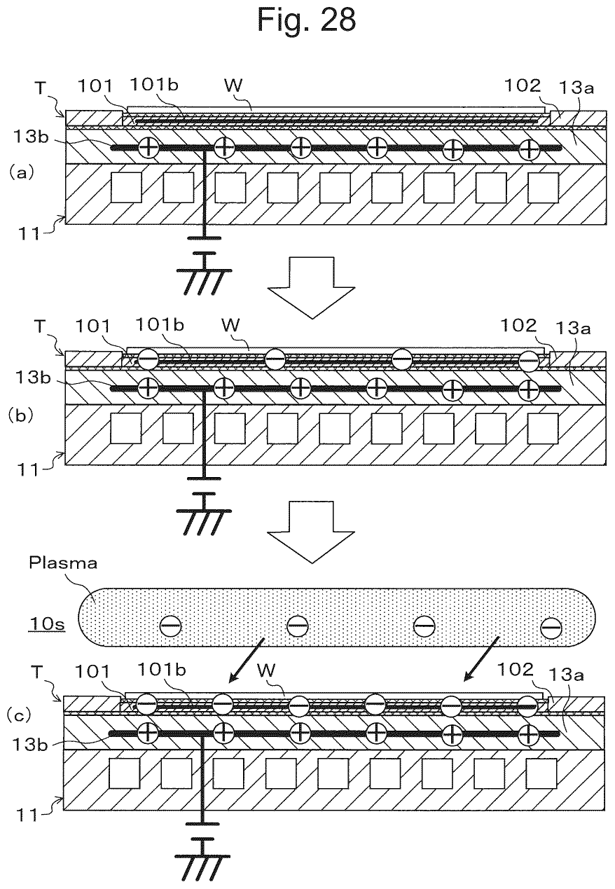

When adsorbing and holding the tray T, first, as illustrated in FIG. 28(a), the voltage (positive (+) charge in the example illustrated in the drawing) is applied to the electrostatic electrode 13b. Then, the electrostatic electrode 13b is positively (+) charged.

When the electrostatic electrode 13b is positively (+) charged, as illustrated in FIG. 28(b), the charge having the polarity (that is, the negative (−)) opposite to the charge accumulated in the electrostatic electrode 13b is accumulated in the charging electrode 101b disposed on the disk portion 101 or the wafer W with the ceramic member 13a being the dielectric and the disk portion 101 being the insulating member interposed therebetween. Then, the Coulomb force is generated in which the charging electrode 101b (the wafer W) and the electrostatic electrode 13b are both polarities, and thus the tray Tw is adsorbed and held on the tray supporting surface of the electrostatic chuck 13.

In addition, even when the disk portion 101 of the tray T is made of the insulating material, the plasma is formed in the wafer processing module 7, so that the Coulomb force can be increased and the adsorption holding force of the electrostatic chuck 13 can be increased. Specifically, as illustrated in FIG. 28(c), by forming the plasma in the plasma processing space 10s, the charge having the polarity opposite to the charge accumulated in the electrostatic electrode 13b (that is, the negative (−)) is moved from the plasma to the charging electrode 101b or the wafer W. That is, the Coulomb force can be increased by supplementing the charge from the plasma, and the tray Tw can be more firmly adsorbed and held.

As described above, even when the disk portion of the tray T is formed of either the conductive member or the insulating member, the tray Tw can be appropriately adsorbed and held on the tray supporting surface by applying the voltage to the electrostatic electrode 13b of the electrostatic chuck 13. In addition, in this case, by forming the plasma in the plasma processing space 10s, the Coulomb force between the tray Tw and the electrostatic chuck 13 is increased, and the tray Tw can be more firmly adsorbed and held.

In addition, by using the Coulomb force in this way, the adsorption and holding of the tray Tw can be controlled only by controlling the voltage applied to the electrostatic electrode 13b. Therefore, the tray Tw can be adsorbed and held without complicating the structure of the support member 11. In addition, since the adsorption and holding can be performed only by the voltage control in this way, the controllability is good, the cooling efficiency of the wafer W can be improved by uniformly controlling the adsorption force in the plane of the tray Tw, that is, uniformly controlling the surface pressure of the tray Tw with respect to the electrostatic chuck 13, and the reproducibility of the adsorption force can be improved.

When the tray Tw is adsorbed and held by the Coulomb force in this way, tilting of the outermost peripheral portion of the wafer W can be controlled by controlling the adsorption force in the plane of the tray Tw when the wafer processing in the wafer processing module 7 is the etching processing as the plasma processing.

When the annular portion 102 of the tray T is worn by the plasma processing and a change occurs in the height of the upper surface of the annular portion 102, a plasma sheath position formed above the outer peripheral portion side of the wafer W is lower than a plasma sheath position formed above the center side of the wafer W, and thus an ion incidence angle with respect to the wafer W is inclined, and an etching groove formed in the outermost peripheral portion of the wafer W is inclined (tilted).

Therefore, in the wafer processing module 7 according to the present embodiment, the electrostatic chuck 13 controls the adsorption force in the plane of the tray Tw (more specifically, two regions of a circular region on the radially inner side and an annular region on the radially outer side) according to the degree of wear (wear amount) of the annular portion 102 of the tray T.

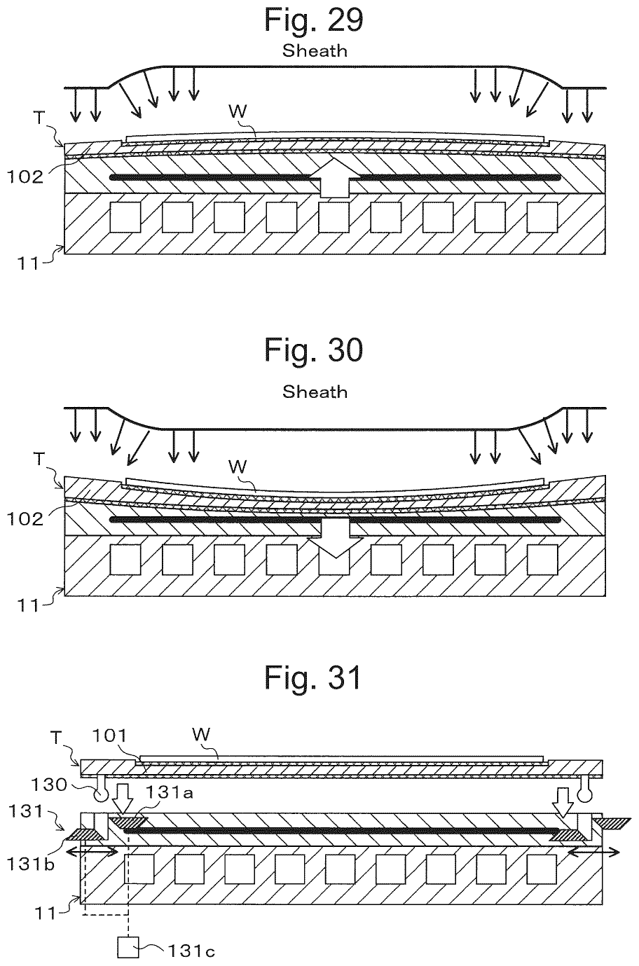

Specifically, for example, by making the adsorption force on the outer peripheral portion side of the tray Tw stronger than the adsorption force on the center portion side of the tray Tw, an adsorption shape of the tray Tw in cross-sectional view is deformed into an upper convex shape as illustrated in FIG. 29. Then, the height of the upper surface of the outer peripheral portion of the wafer W or the annular portion 102 is lower than the height of the upper surface of the center portion of the wafer W, and thus the plasma sheath position formed above the outer peripheral portion side of the wafer W is lowered. As a result, the ion incidence angle can be inclined to the radially inner side of the wafer Was illustrated in FIG. 29.

On the other hand, for example, by making the adsorption force on the outer peripheral portion side of the tray Tw weaker than the adsorption force on the center portion side of the tray Tw, the adsorption shape of the tray Tw in cross-sectional view is deformed into an upper recess shape as illustrated in FIG. 30. Then, the height of the upper surface of the outer peripheral portion of the wafer W or the annular portion 102 is higher than the height of the upper surface of the center portion of the wafer W, and thus the plasma sheath position formed above the outer peripheral portion side of the wafer W is increased, and as illustrated in FIG. 30, the ion incidence angle can be inclined to the radially outer side of the wafer W.

According to the present embodiment, by controlling the adsorption force in the plane of the tray Tw according to the degree of wear (wear amount) of the annular portion 102 of the tray T and the purpose of the etching processing, the ion incidence angle with respect to the wafer W can be controlled, and the tilting of the etching groove formed in the outermost peripheral portion of the wafer W can be controlled.

### (2) Clamp Holding

In the examples illustrated in FIGS. 27 to 30, a case where the tray Tw is electrostatically adsorbed by the electrostatic chuck 13 of the support member 11 is described as an example, but the holding method of the tray Tw with respect to the support member 11 is not limited thereto. Therefore, in the wafer processing module 7, the support member 11 does not necessarily include the electrostatic chuck 13.

Specifically, for example, as illustrated in FIG. 31, a plurality of, for example, two or more pin members 130 may be provided on the lower surface side of the tray T, and the pin members 130 may be inserted into fixing holes formed in the support member 11, and then the tray T and the support member 11 may be mechanically held/fixed by a lock mechanism 131. It is desirable that the pin member 130 and the lock mechanism 131 have a configuration in which the pin member 130 is pulled into the fixing hole (the support member 11) when fixing (locking) the tray T to the support member 11 and the pin member 130 is pressed up with respect to the fixing hole (the support member 11) when being separated (unlocked). As described above, by locking the pin member 130 provided in the tray T to the support member 11, the contact pressure (surface pressure) between the tray T and the support member 11 (the electrostatic chuck 13) is increased, and the heat transfer properties are improved, so that the cooling efficiency of the wafer W can be improved.

The structure of the lock mechanism 131 is not particularly limited as long as it can improve the contact pressure between the support member 11 (the electrostatic chuck 13) and the tray T when fixing (locking) the tray T.

An example of the lock mechanism 131 is a clamp chuck mechanism, and as illustrated in FIG. 31, a press-in member 131a having a tapered shape for pulling in the pin member 130 and a press-out member 131b having a tapered shape for pressing out the pin member 130 may be moved in the horizontal direction by a slide mechanism 131c.

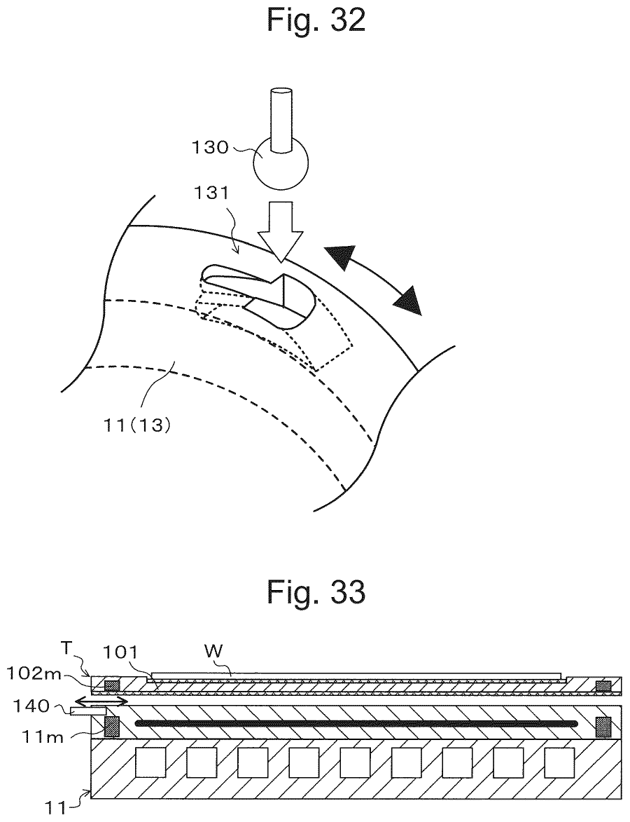

Alternatively, for example, the lock mechanism 131 may be a ring rotation mechanism, and as illustrated in FIG. 32, the lock mechanism 131 may be configured to be relatively rotatable in a circumferential direction with respect to the pin member 130 after the pin member 130 is inserted into the fixing hole. In this case, the rotation mechanism relatively rotating the tray T and the support member 11 may be a motor. In addition, in this case, the ring rotation mechanism may relatively rotate only the lock mechanism 131 with respect to the pin member 130, or may relatively rotate the entire support member 11 with respect to the pin member 130.

When only the lock mechanism 131 is configured to be rotatable, the structure of the lock mechanism 131 can be reduced in size. When the entire support member 11 is configured to be rotatable, the structure of the lock mechanism 131 becomes large. However, when the liquid heat transfer material is supplied via the through-holes 12h and 13h (see FIG. 12), the through-holes 12h and 13h can be moved in the circumferential direction by rotation when the tray T is delivered and when the liquid heat transfer material is supplied. In other words, both the delivery of the tray T and the supply of the liquid heat transfer material can be realized without shifting the position of the through-hole 101h formed in the tray T from the formation positions of the through-holes 12h and 13h in the circumferential direction and/or the radial direction.

### (3) Magnetic Force Holding

In addition, for example, the tray Tw may be adsorbed and held by the support member 11 by a magnetic force.

Specifically, as illustrated in FIG. 33, magnets 102m and 11m are disposed at an outer peripheral portion (a position facing the annular portion 102) corresponding to the annular portion 102 inside the annular portion 102 of the tray T and inside the support member 11. As the magnets 102m and 11m disposed inside the annular portion 102 and the support member 11, an electromagnet or a permanent magnet can be selected.

Then, by disposing the tray Tw above the support member 11 on which the magnet 11m is disposed in such a manner that the magnet 11m and the magnet 102m face each other, a magnetic force with the magnet 11m and the magnet 102m as both polarities is generated, and the tray Tw can be adsorbed and held on the support member 11.

In addition, in this case, for example, as illustrated in FIG. 33, a demagnetizing body 140 is configured to be insertable and removable between the annular portion 102 of the tray Tw and the outer peripheral portion of the support member 11. As a result, the demagnetizing body 140 is disposed between the annular portion 102 and the support member 11, and thus the magnetic force generated between the magnet 11m and the magnet 102m is canceled out, and the tray Tw can be transported from the tray supporting surface of the support member 11.

As described above, in the wafer processing module 7 according to the present embodiment, the tray T may be configured to be adsorbed and held by the support member 11 by disposing the magnet inside each of the tray T and the support member 11.

### (4) Vacuum Adsorption

In addition, the support member 11 of the wafer processing module 7 may include a vacuum chuck instead of the electrostatic chuck 13. In this case, it is desirable that a stretchable sheet heat transfer material is selected as the second heat transfer material 105 disposed on at least the lower surface side of the tray T.

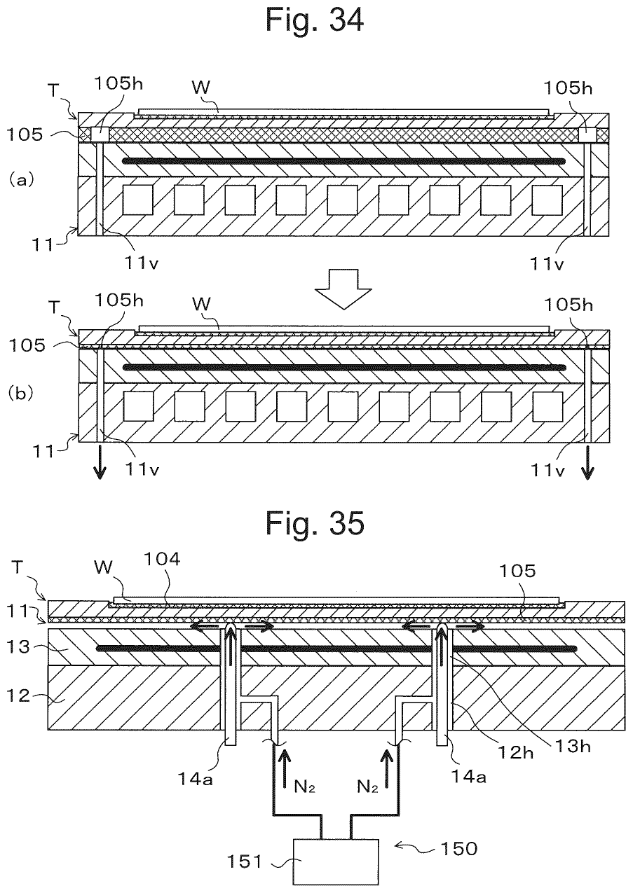

Specifically, for example, as illustrated in FIG. 34(a), a through-hole 105h is formed in the second heat transfer material 105 (the sheet heat transfer material) disposed on the lower surface side of the tray T at a position corresponding to a vacuum line 11v formed in the support member 11 in plan view. Then, as illustrated in FIG. 34(b), a vacuum pump connected to the vacuum line 11v is activated, whereby the tray Tw is adsorbed and held on the tray supporting surface of the support member 11 by the vacuum force.

In addition, in this case, by selecting the sheet heat transfer material having stretchiness as the second heat transfer material 105, the second heat transfer material 105 is compressed in the thickness direction as the tray T is pressed against the tray supporting surface by the vacuum force. As described above, the through-hole 105h is closed by the plastic deformation of the second heat transfer material 105, and the entire surface of the tray T and the entire surface of the support member 11 come into contact with each other on the entire surface via the second heat transfer material 105, so that the tray T can be appropriately vacuum-adsorbed and the cooling efficiency of the wafer W mounted on the tray T can be improved.

<Separating Method of Tray from Electrostatic Chuck>

Next, an example of a separating method of the tray Tw fixed to the support member 11 (the electrostatic chuck 13) as described above from the support member 11 will be described.

As described above, the support member 11 according to the present embodiment is provided with the lifter 14, and the tray Tw is supported from below by the lift pin 14a and is configured to be separable from the tray supporting surface of the support member 11 (the electrostatic chuck 13).

However, when separating the tray Tw and the support member 11 using the lift pin 14a, for example, due to the influence of residual adsorption or vacuum adsorption, there is a concern that the tray Tw cannot be easily peeled off from the tray supporting surface. When the tray Tw is lifted by the lift pin 14a in a state where the residual adsorption or the like is present as described above, there is a concern that the tray T or the wafer W may be damaged due to an overload.

Therefore, in the wafer processing module 7 according to the present embodiment, in order to suppress the damage due to the overload related to the lift-up, an inert gas (for example, an N2 gas) is supplied to the interface between the tray Tw and the support member 11.

More specifically, as illustrated in FIG. 35, a supply flow path 151 of the inert gas connected to a gas supply 150 including a gas supply source is added to the through-holes 12h and 13h into which the lift pin 14a for lifting and lowering the tray Tw is inserted. Then, when the tray Tw is separated, the supply of the inert gas is started prior to the lift of the tray Tw by the lift pin 14a, and thus the interface between the tray Tw and the support member 11 is pressurized to assist the separation of the tray Tw from the support member 11. The gas supply 150 may be shared with the gas supply 20 illustrated in FIG. 2.

According to the present embodiment, by supplying the inert gas when separating the tray Tw from the support member 11 in this way, the tray Tw can be easily removed.

As described above, although three through-holes 12h and 13h for inserting a plurality of, three lift pins 14a in the present embodiment are formed in the support member 11, the inert gas for separating the tray Tw need only be supplied to at least one of the through-holes.

In addition, in the above-described embodiment, the inert gas (N2 gas) is supplied to the interface between the tray Tw and the support member 11, but the supply is not limited to the inert gas as long as the interface between the tray Tw and the support member 11 can be appropriately pressurized under vacuum. Specifically, for example, the above-described ionic liquid may be supplied to the interface between the tray Tw and the support member 11 when the tray Tw is separated.

### Effects of Technique of Present Disclosure

In the wafer processing system 1 according to the technique of the present disclosure described above, the wafer W as a processing target is mounted on the tray T, and the tray T and the wafer W are integrally transported/processed. In addition, the first heat transfer material 104 and the second heat transfer material 105 are disposed at the interface (inside the recess 103) between the tray T and the wafer W, and the interface between the tray T and the support member 11 (the electrostatic chuck 13), respectively, so that the wafer W and the tray T, and the tray T and the support member 11 (the electrostatic chuck 13) come into contact with each other on the entire surface.

As a result, in the wafer processing module 7 according to the technique of the present disclosure, the heat transfer performance from the wafer W to the support member 11 is improved, and the entire surface of the wafer W can be appropriately and uniformly cooled by the heat transfer fluid flowing through the flow path 12a formed in the base 12 of the support member 11.

In addition, since the wafer W and the tray T, and the tray T and the support member 11 (the electrostatic chuck 13) come into contact with each other on the entire surface as described above, a gap as in the related art between the back surface of the wafer W and the outer peripheral portion of the electrostatic chuck 13 is suppressed. Therefore, deposition of a deposit (so-called “shoulder deposit”) on the outer peripheral portion of the electrostatic chuck 13, particularly on a shoulder portion, is suppressed, and the frequency of the cleaning (WLDC: waferless dry cleaning) step of the wafer processing module 7 can be reduced.

In addition, in the wafer processing module 7 according to the technique of the present disclosure, the pressing force (surface pressure) of the tray T against the tray supporting surface of the support member 11 is improved by electrostatic adsorption or clamp holding as described above. As a result, the heat transfer performance from the wafer W to the support member 11 is further improved, and the cooling efficiency of the wafer W can be further improved appropriately.

In the wafer processing module 7 according to the technique of the present disclosure, the wafer W can be uniformly cooled in the plane by interposing the first heat transfer material 104 and the second heat transfer material 105 as described above. However, there is a concern that a temperature singular point where cooling efficiency is decreased occurs in a portion where the through-holes (for example, the through-holes 12h and 13h for the lift pin 14a, the He gas supply hole, the through-hole into which a cable for supplying electrostatic adsorption power or RF power is inserted, or the like) are formed in the plane of the support member 11.

Therefore, in the support member 11 disposed in the wafer processing module 7 according to the present embodiment, it is desirable that the through-holes formed in the support member 11 do not overlap at least the wafer W as a processing target in the vertical direction. More specifically, in the tray Tw held on the tray supporting surface of the support member 11, it is desirable to change the formation positions of the through-holes in such a manner that the through-holes are not formed immediately below the disk portion 101 (the recess 103) on which the wafer W is mounted.

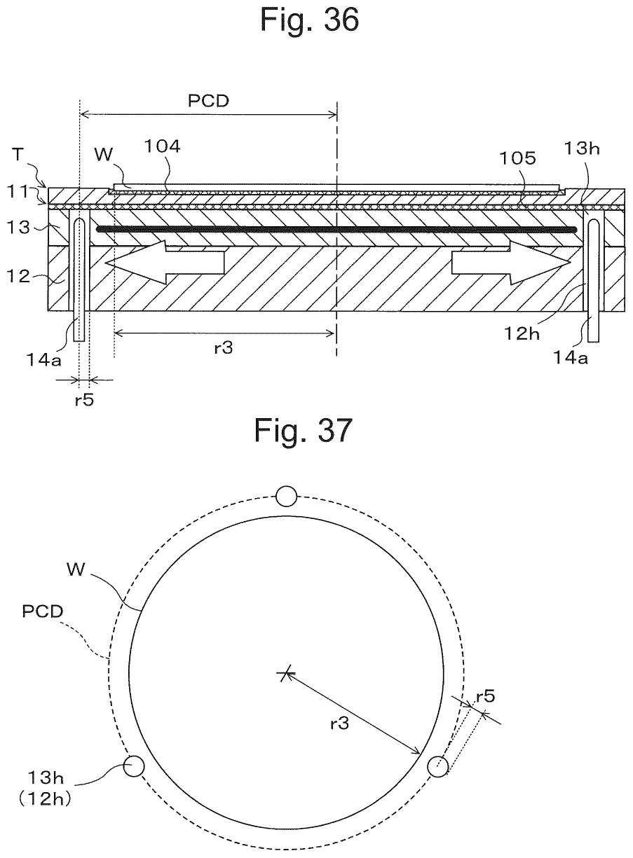

In this case, it is desirable that the positions where the through-holes are formed are directly below the annular portion 102 in the tray T as illustrated in FIGS. 36 and 37. In this case, it is desirable that a pitch circle diameter (PCD) of the through-holes (the through-holes 12h and 13h in the example illustrated in the drawing) is set to be larger than a sum of the outer diameter r3 (see also FIG. 4) of the wafer Was a processing target and a hole diameter r5 of the through-hole (PCD>r3+r5).

According to the present embodiment, the through-holes formed in the support member 11, for example, the through-holes 12h and 13h for the lift pin 14a, the He gas supply hole, the through-hole into which the cable for supplying the electrostatic adsorption power or the RF power is inserted, and the like are disposed so as not to overlap the wafer W in the vertical direction. As a result, the occurrence of a singular point at the in-plane temperature of the wafer W in the wafer processing is suppressed, and the wafer W can be further cooled appropriately.

In the above-described wafer processing system 1, as described above, the deposition of the shoulder deposit on the support member 11 (the electrostatic chuck 13) is suppressed by transporting/processing the tray T on which the wafer W is mounted to the wafer processing module 7, and the cleaning step of the wafer processing module 7 can be reduced. However, in the wafer processing in the wafer processing module 7, the deposit is also attached to the side wall 10a of the plasma processing chamber 10 or the shower head 15 in addition to the shoulder portion of the support member 11, and thus the cleaning step associated with the process is still required.

In this case, when the cleaning (WLDC) step is performed in a state where the tray T is not held on the support member 11 when the tray T is transported integrally with the wafer W as described above, there is a concern that the surface of the support member 11 may be worn due to the influence of the plasma formed in the cleaning step.

Therefore, in the cleaning step of the wafer processing module 7 according to the present embodiment, the tray T in a state where the wafer W as a processing target is not mounted or in a state where a dummy wafer for cleaning is mounted is placed on the support member 11. Hereinafter, the tray T used in the cleaning step may be referred to as a “tray Tc” for convenience. The tray Tc carried into the wafer processing module 7 in the cleaning step may be the same as the tray T on which the wafer Was a processing target is mounted, but it is desirable that the tray Tc is configured of a low-contamination material that does not generate the deposit in the cleaning step, for example, Si, SiC, Al2O3, or Y2O3. In addition, the first heat transfer material 104 and the second heat transfer material 105 may not be provided in the cleaning tray Tc.

In addition, as described above, since it is not always necessary to mount the dummy wafer on the cleaning tray Tc in the cleaning step, the cleaning tray Tc may not be formed with the recess 103 for mounting the wafer W. Therefore, in the cleaning tray Tc, the recess 108 may be formed only on the lower surface side as illustrated in FIG. 10, or may be simply formed in a substantially disk shape which is not illustrated. Therefore, the cleaning tray Tc does not necessarily have the annular portion 102 and may be configured of only the disk portion 101.

In the cleaning step, in a process of removing the deposit attached inside the wafer processing module 7, most of the particle components (removed deposit) are discharged with the exhaust in the plasma processing chamber 10, but a part of the particle components remains in the plasma processing chamber 10, which may affect subsequent process processing.

Therefore, in the cleaning step of the wafer processing module 7, the particle components may be collected by using the Coulomb force or a dielectrophoresis force.

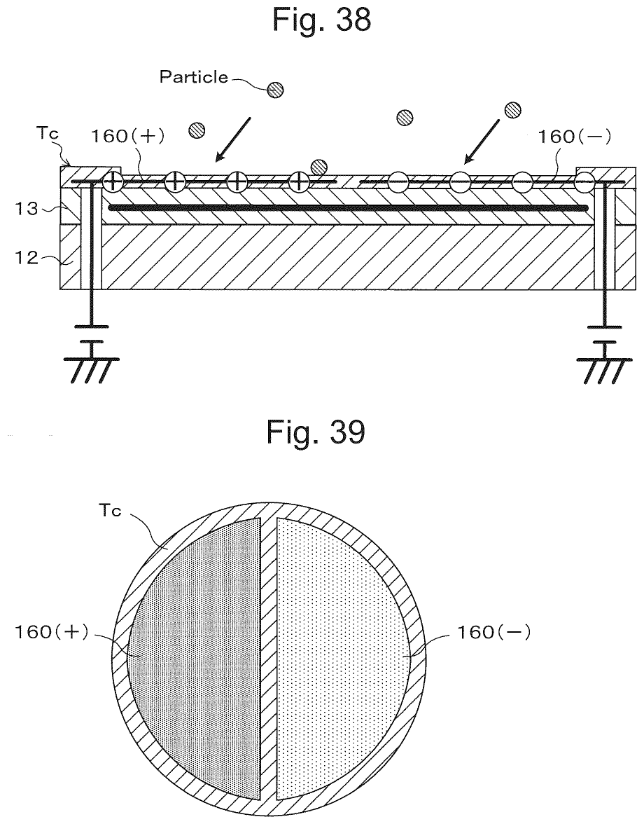

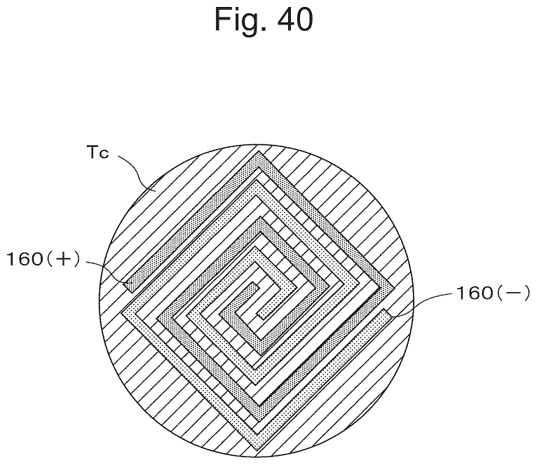

Specifically, for example, as illustrated in FIG. 38 as an example, cleaning electrodes 160 to which the voltage can be applied are disposed in the disk portion 101 of the cleaning tray Tc. It is desirable that the cleaning electrodes 160 have a bipolar structure in which voltages of opposite polarities can be applied to each of the cleaning electrodes 160. In addition, the disposition of the cleaning electrodes 160 in plan view is not particularly limited, but it is preferable to adopt a structure in which a potential difference is likely to occur between two types (bipolar) of electrodes, for example, a structure in which two semicircles are disposed to face each other as illustrated in FIG. 39, or a substantially spiral (helical) disposition as illustrated in FIG. 40.

Then, in the cleaning step, by applying the voltage to the cleaning electrode 160 configured as described above, the particle components are collected on the cleaning tray Tc by the generated Coulomb force and dielectrophoresis force, and the cleaning of the wafer processing module 7 can be performed more appropriately.

The timing of the cleaning step is not particularly limited, and the cleaning step may be executed for each wafer processing in the wafer processing module 7, or may be executed for each predetermined number of processed wafers or for each processing of 25 wafers W in one lot.

In the above description, a case where the wafer processing module 7 is the plasma processing module performing the plasma processing such as etching on the wafer W is described as an example. However, the wafer processing performed by the wafer processing module 7 is not limited to the plasma processing, and for example, the technique according to the present disclosure can be applied to processing in which it is necessary to keep the temperature of the wafer W as a processing target uniformly in the plane.

All the embodiments disclosed herein are considered to be exemplary in all respects and not limiting. The above-described embodiments may be omitted, replaced, or changed in various forms without departing from the scope and the gist of the appended claims. For example, the configuration requirements of the above-described embodiments can be optionally combined. From any combination, the operations and the effects of the respective constitutional requirements related to the combination are naturally obtained, and other operations and other effects which are apparent to those skilled in the art are obtained from the description of the present specification.

In addition, the effects described in the present specification are merely explanatory or exemplary and are not limited. That is, the technique according to the present disclosure can exhibit other effects which are apparent to those skilled in the art from the description of the present specification, together with the above-described effects or instead of the above-described effects. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

According to the present disclosure, the in-plane temperature uniformity of the substrate in the substrate processing can be appropriately improved.

The embodiments disclosed above include, for example, the following aspects.

(Aspect 1) A substrate processing apparatus configured to process a substrate, the substrate processing apparatus including: a processing chamber; and a support member disposed in the processing chamber and having a tray supporting surface for supporting a tray on an upper surface of the support member, in which the tray is formed with a recess accommodating the substrate on an upper surface of the tray via a first heat transfer material, and the tray supporting surface is configured in such a manner that a second heat transfer material is interposed between the tray supporting surface and a lower surface side of the tray.

(Aspect 2) The substrate processing apparatus according to Aspect 1, wherein the tray further includes: a disk portion having a substrate supporting surface on an upper surface of the tray, and an annular portion disposed so as to surround a periphery of the substrate on the substrate supporting surface.

(Aspect 3) The substrate processing apparatus according to Aspect 2, wherein the annular portion has an outer diameter at least larger than an outer diameter of the support member supporting the tray.

(Aspect 4) The substrate processing apparatus according to Aspect 1, wherein the first heat transfer material and the second heat transfer material are a liquid heat transfer material or a sheet heat transfer material.

(Aspect 5) The substrate processing apparatus according to Aspect 4, wherein the liquid heat transfer material is a low vapor pressure liquid.

(Aspect 6) The substrate processing apparatus according to Aspect 5, wherein the low vapor pressure liquid is selected from at least one of an ionic liquid, a silicon liquid, or a fluorine oil.

(Aspect 7) The substrate processing apparatus according to Aspect 4, wherein the sheet heat transfer material is selected from one of a Si-containing material, a SiC-containing material, a W-containing material, a fluorine rubber-based sheet, a silicone sheet, an acrylic sheet, or a mesh sheet.

(Aspect 8) The substrate processing apparatus according to Aspect 2, wherein the support member includes a lift pin configured to lift and lower the tray on the tray supporting surface, the support member is formed with a through-hole into which the lift pin is inserted, and the through-hole does not overlap the disk portion in a plan view.

(Aspect 9) The substrate processing apparatus according to Aspect 8, further comprising a gas supply configured to supply a fluid to an interface between the tray supporting surface and the tray, wherein the gas supply supplies the fluid to the interface between the tray supporting surface and the tray via the through-hole.

(Aspect 10) The substrate processing apparatus according to Aspect 9, wherein the fluid is selected from one of an inert gas or an ionic liquid.

(Aspect 11) A substrate processing apparatus configured to process a substrate, the substrate processing apparatus comprising: a processing chamber; a support member disposed in the processing chamber and having a tray supporting surface on an upper surface; and a tray including: a recess accommodating the substrate on an upper surface, a first heat transfer material disposed in the recess and interposed between the substrate and the tray, and a second heat transfer material disposed on a lower surface side of the tray and interposed between the tray supporting surface and the tray.

(Aspect 12) The substrate processing apparatus according to Aspect 11, wherein the tray further includes: a disk portion having a substrate supporting surface on an upper surface of the tray, and an annular portion disposed so as to surround a periphery of the substrate on the substrate supporting surface.

(Aspect 13) The substrate processing apparatus according to Aspect 12, wherein the annular portion has an outer diameter at least larger than an outer diameter of the support member supporting the tray.

(Aspect 14) The substrate processing apparatus according to Aspect 11, wherein the first heat transfer material and the second heat transfer material are a liquid heat transfer material or a sheet heat transfer material.

(Aspect 15) The substrate processing apparatus according to Aspect 14, wherein the liquid heat transfer material is a low vapor pressure liquid, and the low vapor pressure liquid is selected from at least one of an ionic liquid, a silicon liquid, or a fluorine oil.

(Aspect 16) The substrate processing apparatus according to Aspect 12, wherein the support member includes a lift pin configured to lift and lower the tray on the tray supporting surface, the support member is formed with a through-hole into which the lift pin is inserted, and the through-hole does not overlap the disk portion in a plan view.

(Aspect 17) A substrate processing system configured to process a substrate, the substrate processing system comprising: a tray including an upper surface having a recess for accommodating a substrate; a mounting apparatus configured to mount the substrate on the tray; a transporter configured to hold and transport the tray on which the substrate is mounted; a processing module including a processing chamber and configured to perform desired processing on the substrate; and a separation apparatus configured to separate the substrate from the tray.

(Aspect 18) The substrate processing system according to Aspect 17, wherein the tray includes: a disk portion having a substrate supporting surface on an upper surface of the tray, and an annular portion disposed so as to surround a periphery of the substrate on the substrate supporting surface, and the transporter holds the annular portion of the tray from above to transport the tray.

Aspect (19) The substrate processing system according to Aspect 17, wherein the tray includes: a first heat transfer material disposed in the recess and interposed between the substrate and the tray, and a second heat transfer material disposed on a lower surface side of the tray and interposed between a support member disposed in the processing module and the tray.

(Aspect 20) The substrate processing system according to Aspect 19, further comprising a coating apparatus configured to supply the first heat transfer material to the recess before the substrate is mounted on the tray, and a washing apparatus configured to remove the first heat transfer material remaining in the recess after the substrate is separated from the tray.

What is claimed is:

1. A substrate processing apparatus configured to process a substrate, the substrate processing apparatus comprising:
a processing chamber; and
a support member disposed in the processing chamber and having a tray supporting surface for supporting a tray on an upper surface of the support member,
wherein the tray includes a recess accommodating the substrate on an upper surface of the tray via a first heat transfer material, and
the tray supporting surface includes a second heat transfer material interposed between the tray supporting surface and a lower surface side of the tray.

2. The substrate processing apparatus according to claim 1, wherein the tray further includes:
a disk portion having a substrate supporting surface on an upper surface of the tray, and
an annular portion disposed so as to surround a periphery of the substrate on the substrate supporting surface.

3. The substrate processing apparatus according to claim 2, wherein the annular portion has an outer diameter at least larger than an outer diameter of the support member supporting the tray.

4. The substrate processing apparatus according to claim 1, wherein the first heat transfer material and the second heat transfer material are a liquid heat transfer material or a sheet heat transfer material.

5. The substrate processing apparatus according to claim 4, wherein the liquid heat transfer material is a low vapor pressure liquid.

6. The substrate processing apparatus according to claim 5, wherein the low vapor pressure liquid is selected from at least one of an ionic liquid, a silicon liquid, or a fluorine oil.

7. The substrate processing apparatus according to claim 4, wherein the sheet heat transfer material is selected from one of a Si-containing material, a SiC-containing material, a W-containing material, a fluorine rubber-based sheet, a silicone sheet, an acrylic sheet, or a mesh sheet.

8. The substrate processing apparatus according to claim 2,
wherein the support member includes a lift pin configured to lift and lower the tray on the tray supporting surface,
the support member is formed with a through-hole into which the lift pin is inserted, and
the through-hole does not overlap the disk portion in a plan view.

9. The substrate processing apparatus according to claim 8, further comprising:
a gas supply configured to supply a fluid to an interface between the tray supporting surface and the tray,
wherein the gas supply supplies the fluid to the interface between the tray supporting surface and the tray via the through-hole.

10. The substrate processing apparatus according to claim 9, wherein the fluid is selected from one of an inert gas or an ionic liquid.

11. A substrate processing apparatus configured to process a substrate, the substrate processing apparatus comprising:
a processing chamber;
a support member disposed in the processing chamber and having a tray supporting surface on an upper surface; and
a tray including:
a recess accommodating the substrate on an upper surface,
a first heat transfer material disposed in the recess and interposed between the substrate and the tray, and
a second heat transfer material disposed on a lower surface side of the tray and interposed between the tray supporting surface and the tray.

12. The substrate processing apparatus according to claim 11, wherein the tray further includes:
a disk portion having a substrate supporting surface on an upper surface of the tray, and
an annular portion disposed so as to surround a periphery of the substrate on the substrate supporting surface.

13. The substrate processing apparatus according to claim 12, wherein the annular portion has an outer diameter at least larger than an outer diameter of the support member supporting the tray.

14. The substrate processing apparatus according to claim 11, wherein the first heat transfer material and the second heat transfer material are a liquid heat transfer material or a sheet heat transfer material.

15. The substrate processing apparatus according to claim 14, wherein the liquid heat transfer material is a low vapor pressure liquid, and
the low vapor pressure liquid is selected from at least one of an ionic liquid, a silicon liquid, or a fluorine oil.

16. The substrate processing apparatus according to claim 12, wherein the support member includes a lift pin configured to lift and lower the tray on the tray supporting surface,
the support member is formed with a through-hole into which the lift pin is inserted, and
the through-hole does not overlap the disk portion in a plan view.

17. A substrate processing system configured to process a substrate, the substrate processing system comprising:
a tray including an upper surface having a recess for accommodating a substrate;
a mounting apparatus configured to mount the substrate on the tray;
a transporter configured to hold and transport the tray on which the substrate is mounted;
a processing module including a processing chamber and configured to perform desired processing on the substrate; and
a separation apparatus configured to separate the substrate from the tray.

18. The substrate processing system according to claim 17, wherein the tray includes:
a disk portion having a substrate supporting surface on an upper surface of the tray, and
an annular portion disposed so as to surround a periphery of the substrate on the substrate supporting surface, and
the transporter holds the annular portion of the tray from above to transport the tray.

19. The substrate processing system according to claim 17, wherein the tray includes:
a first heat transfer material disposed in the recess and interposed between the substrate and the tray, and
a second heat transfer material disposed on a lower surface side of the tray and interposed between a support member disposed in the processing module and the tray.

20. The substrate processing system according to claim 19, further comprising
a coating apparatus configured to supply the first heat transfer material to the recess before the substrate is mounted on the tray, and
a washing apparatus configured to remove the first heat transfer material remaining in the recess after the substrate is separated from the tray.
